(19) United States
(12) Patent Application Publication
(10) Pub. No.: US 2026/0045309 A1
(43) Pub. Date: Feb. 12, 2026

(54) MEMORY DEVICE AND PROGRAMMING METHOD OF MEMORY DEVICE

(71) Applicant: SAMSUNG ELECTRONICS CO., LTD., Suwon-si (KR)

(72) Inventors: Shinkeun Kim, Suwon-si (KR); Joonsuc Jang, Suwon-si (KR); Nayoung Choi, Suwon-si (KR); Jisang Lee, Suwon-si (KR)

(21) Appl. No.: 19/198,916

(22) Filed: May 5, 2025

(30) Foreign Application Priority Data
Aug. 8, 2024 (KR) 10-2024-0106335

(51) Int. Cl. G11C 16/34; G11C 16/08

(52) U.S. Cl. CPC G11C 16/3404; G11C 16/08; G11C 16/3454

(57) ABSTRACT

Semiconductor devices and methods for operating the semiconductor devices are provided. In one aspect, a memory device includes a plurality of memory cells connected to a plurality of word lines including a first group of word lines and a second group of word lines; and a control logic. The control logic is configured to: in a bit line setup period, perform a setup operation of applying a string selection line voltage to string selection lines connected to at least one of the cell strings to activate the string selection lines; in a first recovery period before the setup operation is performed, apply a first recovery voltage to the first group of word lines; and in a second recovery period after the first recovery period, apply a second recovery voltage to the second group of word lines

### CROSS-REFERENCE TO RELATED APPLICATION

This application is based on and claims priority under 35 U.S.C. § 119 to Korean Patent Application No. 10-2024-0106335, filed on Aug. 8, 2024, in the Korean Intellectual Property Office, the disclosure of which is incorporated by reference herein in its entirety.

### BACKGROUND

A nonvolatile memory device as a memory device includes a plurality of memory cells that non-volatilely store data. A flash memory as a nonvolatile memory may maintain stored data even when power is cut off. As an example of a nonvolatile memory device, a flash memory device may be used in a mobile phone, a digital camera, a portable information terminal (PDA), a mobile computer device, a stationary computer device, and other devices.

According to the demand for high capacity and miniaturization of nonvolatile memory devices, a memory device including a plurality of cell strings extending in a vertical direction on a substrate has been developed. An example of a programming method performed in a memory device includes incremental step pulse programming (hereinafter referred to as ‘ISPP’). According to an ISPP method, a plurality of program loops may be performed until a program is completed. Each of the program loops may include a program operation, a verify operation, and a recovery operation of initializing channels of a plurality of cell strings.

With ISPP, some channels corresponding to programmed memory cells may be negatively boosted, which may cause a program disturbance or hot carrier injection (HCI), and deteriorate the reliability of a nonvolatile memory device.

### SUMMARY

The present disclosure provides a memory device capable of reducing a program time by applying a voltage to a string selection line after performing a recovery operation on some word lines and a programming method of the memory device.

According to an aspect of the present disclosure, a memory device is provided, which includes a memory cell array including cell strings in which a plurality of memory cells connected to a plurality of word lines are disposed in series, and a control logic configured to perform a program verify operation on a selected memory cell among the plurality of memory cells in the verify period and recover the plurality of word lines after the verify period, wherein the control logic is configured to perform a setup operation of applying a string selection line voltage to string selection lines connected to the cell strings to activate the string selection lines, in a bit line setup period, apply a recovery voltage to some word lines of the plurality of word lines, in a first recovery period before the setup operation is performed, and apply the recovery voltage to remaining word lines among the plurality of word lines, in a second recovery period after the first recovery period.

According to another aspect of the present disclosure, a programming method of a memory device is provided. The memory device includes cell strings in which a plurality of memory cells connected to a plurality of word lines are disposed in series including performing a program verify operation on a selected memory cell among the plurality of memory cells, applying a recovery voltage to pre word lines among the plurality of word lines, applying a string selection line voltage to string selection lines connected to the cell strings to activate the string selection lines, and applying the recovery voltage to post word lines among the plurality of word lines, wherein the applying of the recovery voltage to the pre word lines precedes the applying of the string selection line voltage to the string selection lines.

According to another aspect of the present disclosure, a memory device is provided, which includes a memory cell array including a plurality of cell strings in which a string selection transistor, memory cells connected to a plurality of word lines, and a ground selection transistor are disposed in series, and a control logic configured to recover the plurality of word lines, wherein the plurality of word lines include a selected word line, upper word lines on which a program operation is performed before being performed on the selected word line, and lower word lines on which the program operation is performed after being performed on the selected word line, the control logic is configured to turn on the ground selection transistor in a verify period, apply a recovery voltage to at least some of the upper word lines in a first recovery period after the verify period, turn on the string selection transistor in a bit line setup period after the first recovery period, and apply the recovery voltage to the upper word line to which the recovery voltage is not applied in the first recovery period, the selected word line, and the lower word line in a second recovery period, and at least a part of the bit line setup period overlaps the second recovery period.

### BRIEF DESCRIPTION OF THE DRAWINGS

Implementations will be more clearly understood from the following detailed description taken in conjunction with the accompanying drawings in which:

FIG. 1 is a block diagram illustrating an example memory system;

FIG. 2 is a diagram illustrating an example memory device;

FIG. 3 is an example circuit diagram illustrating a memory block;

FIG. 4A is a perspective view illustrating an example memory block;

FIG. 4B is a perspective view illustrating an example memory block;

FIG. 5A schematically illustrates an example memory cell array;

FIG. 5B schematically illustrates an example memory cell array;

FIG. 6 is an example voltage potential graph for each memory cell for explaining a program disturbance phenomenon;

FIG. 7 is a diagram for explaining example program loops;

FIG. 8 is an example timing diagram illustrating operation of a memory device;

FIG. 9 is an example timing diagram for explaining operation of a memory device;

FIG. 10 is an example timing diagram for explaining a first recovery operation;

FIG. 11 is an example timing diagram for explaining a second recovery operation;

FIG. 12 is an example timing diagram for explaining a first recovery operation and a second recovery operation,;

FIG. 13 is an example timing diagram for explaining performing a first recovery operation on an uppermost word line;

FIG. 14 is a diagram for explaining a bit line setup period and a second recovery period;

FIG. 15 is an example timing diagram illustrating operation of a memory device;

FIG. 16 is an example timing diagram illustrating operation of a memory device;

FIG. 17 is a timing diagram for explaining a first recovery operation and a second recovery operation,;

FIG. 18 is a flowchart illustrating an example programming method of a memory device;

FIG. 19 is a cross-sectional view illustrating an example memory device having a B-VNAND structure; and

FIG. 20 is a block diagram illustrating a solid-state drive (SSD) system to which an example memory device is applied.

### DETAILED DESCRIPTION

Hereinafter, an implementation of the present disclosure will be described in detail with reference to the accompanying drawings. The same reference numerals are used for the same components in the drawings, and redundant descriptions thereof are omitted.

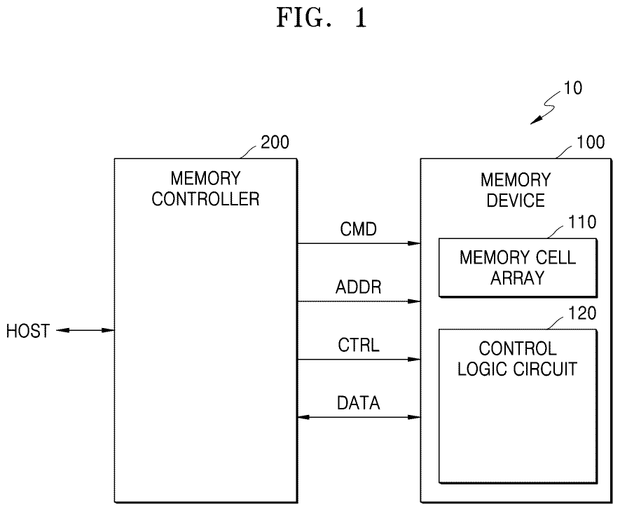

FIG. 1 is a block diagram illustrating a memory system 10 according to one or more implementations.

Referring to FIG. 1, the memory system 10 may include a memory device 100 and a memory controller 200, and the memory device 100 may include a memory cell array 110 and a control logic 120.

For example, the memory controller 200 and the memory device 100 may be integrated into a single semiconductor device. For example, the memory system 10 may be implemented as an internal memory embedded in an electronic device, and may be an embedded universal flash storage (UFS) memory device, an embedded multi-media card (eMMC), or a solid state drive (SSD). In some implementations, the memory system 10 may be implemented as an external memory detachable from the electronic device, for example, a UFS memory card, compact flash (CF), secure digital (SD), micro-SD, mini-SD, extreme digital (xD), or a memory stick. However, the present disclosure is not necessarily limited thereto.

The memory controller 200 may control the memory device 100 to read data stored in the memory device 100 or to program data in the memory device 100 in response to a read/write request from a host HOST. Specifically, the memory controller 200 may control program, read, and erase operations on the memory device 100 by providing an address ADDR, a command CMD, and a control signal CTRL to the memory device 100. In addition, data DATA for programming and the read data DATA may be transmitted and received between the memory controller 200 and the memory device 100.

Although not shown, the memory controller 200 may include a RAM, a processing unit, a host interface, and a memory interface. The RAM may be used as an operation memory of the processing unit, and the processing unit may control an operation of the memory controller 200. The host interface may include a protocol for performing data exchange between the host HOST and the memory controller 200. For example, the memory controller 200 may be configured to communicate with the host HOST through at least one of various interface protocols such as Universal Serial Bus (USB), MMC, Peripheral Component Interconnect Express (PCI-E), Advanced Technology Attachment (ATA), Serial-ATA, Parallel-ATA, SCSI, ESDI, and Integrated Drive Electronics (IDE).

The memory device 100 may perform the erase operation, the program operation, or the read operation by the control of the memory controller 200. The memory device 100 receives the command CMD and the address ADDR from the memory controller 200 through an input/output line, and transmit and receive the data DATA for the program operation or the read operation to and from the memory controller 200. Also, the memory device 100 may receive a control signal CTRL through a control line.

The memory device 100 may include one or more memory cell arrays 110. The memory cell array 110 may include a plurality of memory cells disposed in areas where a plurality of word lines and a plurality of bit lines cross each other, and the plurality of memory cells may be nonvolatile memory cells.

The memory device 100 may include a nonvolatile memory device such as a flash memory. The memory device 100 may include various types of memories. For example, the memory device 100 may include NAND flash memory, vertical NAND (VNAND), NOR flash memory, resistive random access memory (RRAM), phase-change memory (PRAM), magnetoresistive random access memory (MRAM), ferroelectric random access memory (FRAM), spin injection magnetic random access memory (STT-RAM), etc., but is not limited thereto.

The memory cell array 110 may include a plurality of memory cells, and, for example, the plurality of memory cells may be flash memory cells. Hereinafter, implementations of the present disclosure will be described in detail with reference to a case in which the plurality of memory cells are NAND flash memory cells. However, the present disclosure is not limited thereto, and the plurality of memory cells may be various types of nonvolatile memory cells. In some implementations, the plurality of memory cells may be resistive memory cells such as RRAM, PRAM, or MRAM.

In some implementations, the memory cell array 110 may include a plurality of cell strings sharing a bit line. Each of the plurality of cell strings may include a ground selection transistor connected to a ground selection line, word lines, and a string selection line, memory cells, and string selection transistors. The memory cell array 110 may be a two-dimensional (2D) memory array. Alternatively, the memory cell array 110 may be a three-dimensional (3D) memory array.

The 3D memory array may be monolithically formed on at least one physical level of memory cell arrays having an active area disposed on a silicon substrate and a circuit related to operations of memory cells and formed on or within the substrate. The term “monolithic” may mean that layers of each of levels constituting the array are stacked directly above layers of each of lower levels in the array. The 3D memory array may include cell strings disposed in a vertical direction such that at least one memory cell is located above another memory cell. The at least one memory cell may include a charge trap layer.

The control logic 120 may control overall operations of the memory device 100. For example, the control logic 120 may receive the command CMD, the address ADDR, and the control signal CTRL from the memory controller 200 and control the overall operations of the memory device 100 based on the received command CMD, address ADDR, and control signal CTRL. The control logic 120 may generate various internal control signals used in the memory device 100 in response to the control signal CTRL provided from the memory controller 200. For example, the control logic 120 may adjust voltage levels provided to word lines and bit lines when performing a memory operation such as the program or erase operation.

The control logic 120 may control the program operation on the memory cells included in the memory cell array 110. For example, when the command CMD, the address ADDR, and the data DATA corresponding to a program command are received from the memory controller 200, the control logic 120 may write the received data DATA to the memory cell array 110 by controlling the program operation on a selected word line or a selected memory cell corresponding to the address ADDR.

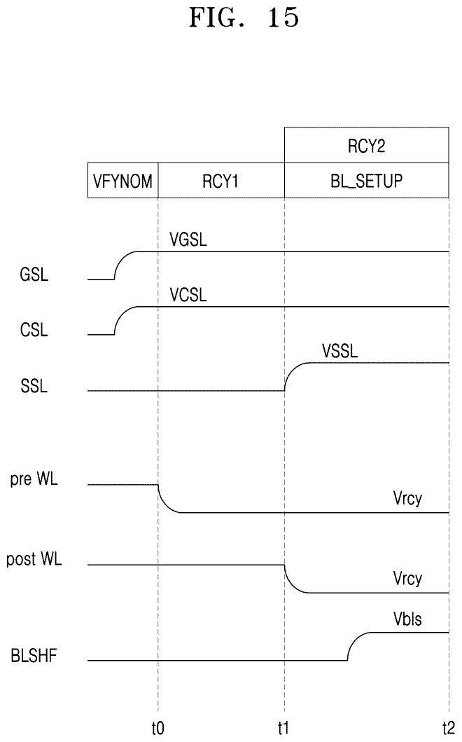

During the memory operation, the program operation or the erase operation may include a plurality of loops. Herein, the program operation will be mainly described, but the present disclosure is not necessarily limited thereto. For example, the program operation may be performed using an incremental step pulse program (ISPP) method. Each of the plurality of program loops included in the program operation may include one or more periods. For example, one program loop may include a program execution period (e.g., PGM_EXE of FIG. 15), a bit line setup period (e.g., BL_SETUP of FIG. 15), a verify period (e.g., VFYNOM of FIG. 15), and a recovery period (e.g., RCY of FIG. 15).

The control logic 120 may perform a recovery operation on word lines. The recovery operation may mean an operation of applying a recovery voltage to a word line, and a period in which the recovery operation is performed may be the recovery period. The control logic 120 may sequentially perform the recovery operation on a plurality of word lines. That is, the control logic 120 may group a plurality of word lines into two or more groups and apply a recovery voltage to each group at different times. For example, the control logic 120 may perform a sequential recovery operation of performing the recovery operation on a specific word line, and then performing the recovery operation on another word line. The control logic 120 may sequentially perform the recovery operation, thereby suppressing negative boosting in a channel area and reducing program disturbance.

The control logic 120 may first perform the recovery operation on some of the plurality of word lines. The control logic 120 may perform the recovery operation on some word lines before a setup operation of the bit line setup period, which may be referred to as a first recovery operation. Some of the plurality of word lines on which the recovery operation is performed before the setup operation of the bit line setup period may be referred to as pre word lines.

The control logic 120 may perform the recovery operation on some of the plurality of word lines, and then perform the recovery operation on the remaining word lines. The control logic 120 may perform the recovery operation on the remaining word lines on which the first recovery operation is not performed, which may be referred to as a second recovery operation. The control logic 120 may perform the first recovery operation, and then perform the second recovery operation. The remaining word lines on which the first recovery operation is not performed may be referred to as post word lines.

The recovery period may include a first recovery period and a second recovery period. A period in which the first recovery operation is performed may be the first recovery period, and the control logic 120 may apply recovery voltages to some of the plurality of word lines in the first recovery period. A period in which the second recovery operation is performed may be the second recovery period, and the control logic 120 may apply recovery voltages to the remaining word lines in the second recovery period. That is, the recovery voltage may be applied to the pre word line in the first recovery period, and the recovery voltage may be applied to the post word line in the second recovery period.

The second recovery period may be after the first recovery period. The control logic 120 may perform the first recovery operation, and then perform the first recovery operation. That is, the control logic 120 may perform the first recovery operation on some of the plurality of word lines, and then perform the second recovery operation on the remaining word lines on which the first recovery operation has not been performed. The control logic 120 may perform the first recovery operation on the pre word line and then perform the second recovery operation on the post word line.

The control logic 120 may control the recovery operation and the setup operation. The setup operation may refer to an operation in which string selection line voltages are applied to string selection lines to activate the string selection lines connected to cell strings in the bit line setup period. The control logic 120 may turn on a string selection transistor by applying a string selection line voltage. A word line recovered before the setup operation may be the pre word line, and the recovery operation performed before the setup operation may be the first recovery operation. The recovery operation performed after the setup operation or simultaneously with the setup operation may be the second recovery operation, and a word line recovered after the setup operation or simultaneously with the setup operation may be the post word line. The control logic 120 may first perform the first recovery operation on the pre word line before applying the string selection line voltage in the bit line setup period.

In some implementations, the bit line setup period may start, and then the second recovery period may start. The control logic 120 may apply the string selection line voltage to the string selection lines in the bit line setup period, and then apply the recovery voltage to the post word line in the second recovery period. The control logic 120 may start the setup operation of the bit line setup period after performing the first recovery operation, and then perform the second recovery operation. That is, the setup operation of the bit line setup period may start after the first recovery period, and then the second recovery period may proceed.

The second recovery operation is performed after the setup operation starts in the bit line setup period, and thus, a part of the bit line setup period may overlap the second recovery period. The second recovery period starts after the setup operation of the bit line setup period starts, the second recovery operation starts early, and thus, even while the second recovery operation is performed, an operation in the bit line setup period after the setup operation may be performed, and the entire program time may be reduced.

In some implementations, the bit line setup period and the second recovery period may start simultaneously. The control logic 120 may apply the string selection line voltage to the string selection lines in the bit line setup period and simultaneously apply the recovery voltage to the post word line in the second recovery period. The control logic 120 may perform the first recovery operation, and then simultaneously start the setup operation and the second recovery operation of the bit line setup period. That is, after the first recovery period, the setup operation and the second recovery period may proceed.

The setup operation and the second recovery operation start simultaneously in the bit line setup period, and thus, the bit line setup period and the second recovery period may overlap. The bit line setup period and the second recovery period start simultaneously, and thus, a separate overhead may not be required for the setup operation, and the entire program time may be reduced, thereby improving the performance of the memory device 100.

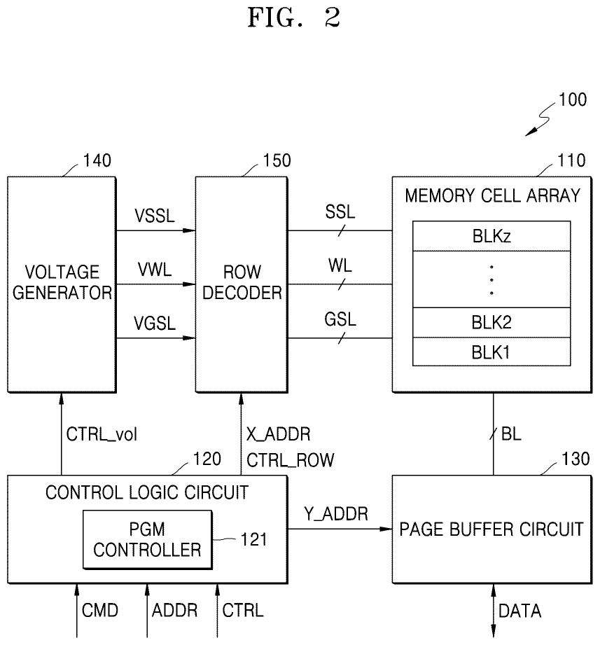

FIG. 2 is a diagram illustrating the memory device 100 according to one or more implementations. The memory device 100, the memory cell array 110, and the control logic 120 of FIG. 2 respectively correspond to the memory device 100, the memory cell array 110, and the control logic 120 of FIG. 1, and thus, redundant descriptions thereof are omitted.

Referring to FIG. 2, the memory device 100 may include the memory cell array 110, the control logic 120, a page buffer circuit 130, a voltage generator 140, and a row decoder 150. Although not shown, the memory device 100 may further include an interface circuit, and the interface circuit may include a data input/output circuit, or a command/address input/output circuit.

The memory cell array 110 may include a plurality of memory blocks BLK1 to BLKz, and z is a positive integer. Each of the plurality of memory blocks BLK1 to BLKz may include a plurality of pages, and each of the plurality of pages may include a plurality of memory cells. For example, a memory block may be a unit of erase, and a page may be a unit of write and read. Each memory cell may store one or more bits, and specifically, each memory cell may be used as a single level cell (SLC), a multi-level cell (MLC), a triple level cell (TLC), or a quadruple level cell (QLC). However, the present disclosure is not necessarily limited thereto.

The memory cell array 110 may be connected to a plurality of word lines WL, a plurality of string selection lines SSL, a plurality of ground selection lines GSL, and a plurality of bit lines BL. The memory cell array 110 may be connected to the row decoder 150 through a plurality of word lines WL, a plurality of string selection lines SSL, and the plurality of ground selection lines GSL, and may be connected to the page buffer circuit 130 through the plurality of bit lines BL. In some implementations, the memory cell array 110 may be further connected to gate induced drain loss (GIDL) erase control lines.

The control logic 120 may output various control signals for writing data to the memory cell array 110 or reading data from the memory cell array 110 based on the command CMD, the address ADDR, and the control signal CTRL received from the memory controller (e.g., 200 of FIG. 1). Thus, the control logic 120 may control generally various operations in the memory device 100. Specifically, the control logic 120 may provide a voltage control signal CTRL_vol to the voltage generator 140, a row address X_ADDR to the row decoder 150, and a column address Y_ADDR to the page buffer circuit 130. However, the present disclosure is not limited thereto, and the control logic 120 may further provide other control signals to the voltage generator 140, the row decoder 150, and the page buffer circuit 130. For example, the control logic 120 may provide a row decoder control signal CTRL_ROW to the row decoder 150, and the row decoder 150 may control the recovery period and the bit line setup period based on the row decoder control signal CTRL_ROW.

The control logic 120 may include a program controller 121. The program controller 121 may control a program operation with respect to the memory cells included in the memory cell array 110. The program controller 121 may control a recovery operation on the word lines WL during the recovery period. The program controller 121 may perform the recovery operation on the word lines WL. For example, the program controller 121 may provide the row decoder control signal CTRL_ROW to the row decoder 150 to perform the recovery operation on the word lines WL. The program controller 121 may group a plurality of word lines WL into two or more groups and sequentially perform the recovery operation.

In addition, the program controller 121 may control a setup operation on the string selection lines SSL in the bit line setup period. The program controller 121 may perform the setup operation on the string selection lines SSL. For example, the program controller 121 may provide the row decoder control signal CTRL_ROW to the row decoder 150 to perform the setup operation on the string selection lines SSL. The control logic 120 transmits the row address X_ADDR and the row decoder control signal CTRL_ROW to the row decoder 150 through one line, but is not necessarily limited thereto, and the control logic 120 may transmit the row address X_ADDR and the row decoder control signal CTRL_ROW to the row decoder 150 through different lines.

The program controller 121 may perform a first recovery operation on a pre word line and may perform a second recovery operation on a post word line, among the plurality of word lines WL. The program controller 121 may control the row decoder 150 to perform the first recovery operation, and then perform the second recovery operation.

The program controller 121 may first perform the first recovery operation on the pre word line before applying a string selection line voltage VSSL to the string selection line SSL in the bit line setup period. In some implementations, the program controller 121 may generate the row decoder control signal CTRL_ROW so that after a recovery voltage is applied to the pre word line, the string select line voltage VSSL is applied to the string select lines SSL in the bit line setup period, and then the recovery voltage is applied to the post word line. The program controller 121 may start the setup operation of the bit line setup period after performing the first recovery operation, and then perform the second recovery operation.

In some implementations, the program controller 121 may control the setup operation of the bit line setup period and the second recovery period to start simultaneously. The program controller 121 may generate the row decoder control signal CTRL_ROW so that the string selection line voltage VSSL is applied to the string selection lines SSL in the bit line setup period and simultaneously the recovery voltage is applied to the post word line in the second recovery period. The program controller 121 may perform the first recovery operation, and then simultaneously start the setup operation and the second recovery operation of the bit line setup period.

The voltage generator 140 may generate various types of voltages for performing program, read, and erase operations based on the voltage control signal CTRL_vol. Specifically, the voltage generator 140 may generate a word line voltage VWL, a string selection line voltage VSSL, and a ground selection line voltage VGSL, and may provide the generated word line voltage VWL, string selection line voltage VSSL, and ground selection line voltage VGSL to the row decoder 150. For example, the voltage generator 140 may generate a program voltage, a pass voltage, a read voltage, a program verification voltage, a recovery voltage, and an erase voltage as the word line voltage VWL. Also, the voltage generator 140 may further generate a bit line voltage and a common source line voltage.

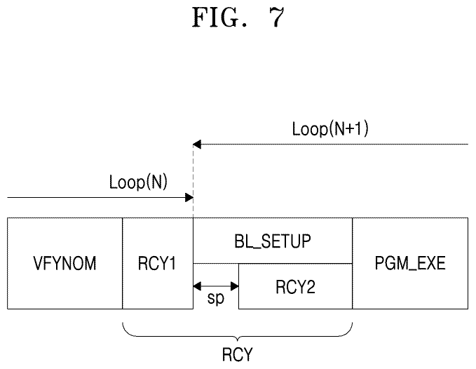

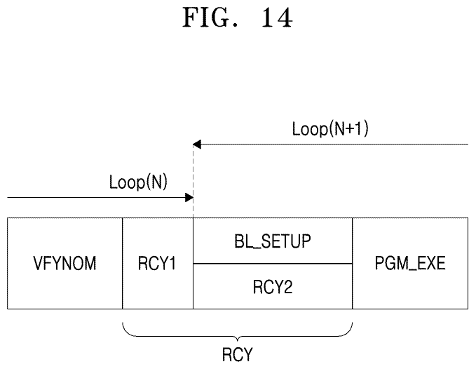

The voltage generator 140 may generate the recovery voltage for the recovery operation on the word line WL based on the voltage control signal CTRL_vol. The voltage generator 140 may generate a first recovery voltage to be applied to the pre word line in a first recovery period (e.g., RCY1 of FIGS. 7 and 14) for the first recovery operation based on the voltage control signal CTRL_vol. The voltage generator 140 may generate a second recovery voltage to be applied to the post word line in a second recovery period (e.g., RCY2 of FIGS. 7 and 14) for the second recovery operation based on the voltage control signal CTRL_vol.

In some implementations, the voltage generator 140 may generate a first recovery voltage and a second recovery voltage having the same level. Recovery voltages having the same level may be applied in the first recovery period and the second recovery period. For example, all the word lines WL may be recovered with recovery voltages having the same level. However, the present disclosure is not necessarily limited thereto. The voltage generator 140 may generate a first recovery voltage and a second recovery voltage having different levels based on the voltage control signal CTRL_vol. In addition, the voltage generator 140 may generate first recovery voltages of different levels in the first recovery period based on the voltage control signal CTRL_vol. The voltage generator 140 may generate first recovery voltages having different levels according to the pre word line in the first recovery period. In addition, the voltage generator 140 may generate second recovery voltages of different levels in the second recovery period based on the voltage control signal CTRL_vol. The voltage generator 140 may generate second recovery voltages having different levels according to the pre word line in the second recovery period.

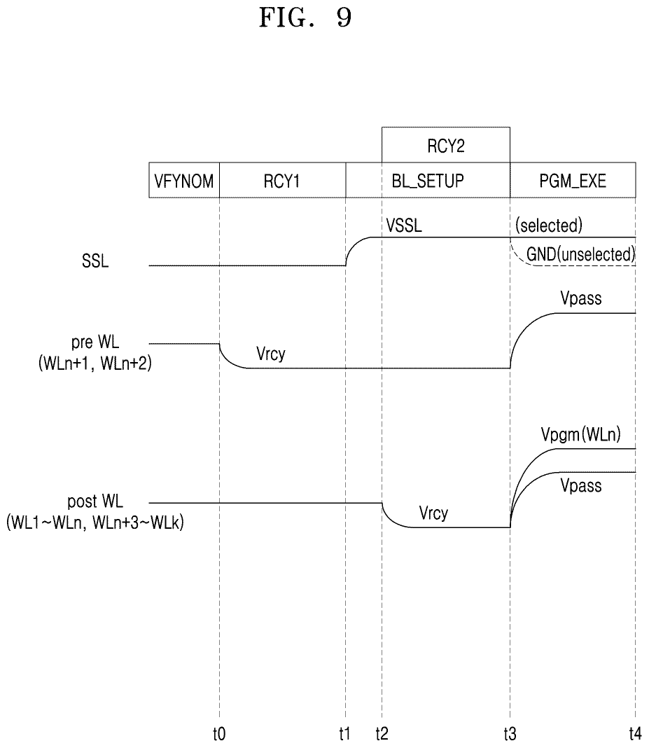

The row decoder 150 may select one of the plurality of word lines WL and may select one of the plurality of string selection lines SSL, in response to the row address X_ADDR. For example, during the program operation, the row decoder 150 may apply a program voltage (e.g., Vpgm of FIG. 9) to the selected word line in a program execution period and a program verification voltage to the selected word line in a verify period.

The row decoder 150 may apply the recovery voltage to the word line WL based on the row decoder control signal CTRL_ROW. For example, during the first recovery operation, the row decoder 150 may apply a recovery voltage to the pre word line based on the row decoder control signal CTRL_ROW in the first recovery period. For example, during the second recovery operation, the row decoder 150 may apply a recovery voltage to the post word line based on the row decoder control signal CTRL_ROW in the second recovery period.

The row decoder 150 may apply the string selection line voltage VSSL to the string selection line SSL based on the row decoder control signal CTRL_ROW. In some implementations, in the bit line setup period after the first recovery period, the row decoder 150 may apply the string selection line voltage VSSL to the string selection line SSL based on the row decoder control signal CTRL_ROW before applying the recovery voltage to the post word line.

In addition, in an implementation, in the bit line setup period after the first recovery period, the row decoder 150 may simultaneously apply the recovery voltage to the post word line and the string selection line voltage VSSL to the string selection line SSL based on the row decoder control signal CTRL_ROW.

The page buffer circuit 130 may be connected to the memory cell array 110 through the plurality of bit lines BL. The page buffer circuit 130 may select at least one of the plurality of bit lines BL in response to the column address Y-ADDR received from the control logic 120. The page buffer circuit 130 may temporarily store data read from the memory cell array 110, or may temporarily store data to be stored in the memory cell array 110.

For example, the page buffer circuit 130 may include a plurality of page buffers connected to the plurality of bit lines BL, respectively. The plurality of page buffers may be disposed corresponding to each bit line, and each page buffer may include a plurality of latches. However, the present disclosure is not necessarily limited thereto, and one page buffer may be provided corresponding to a plurality of bit lines. The page buffer circuit 130 may operate as a write driver or a sense amplifier according to an operation mode.

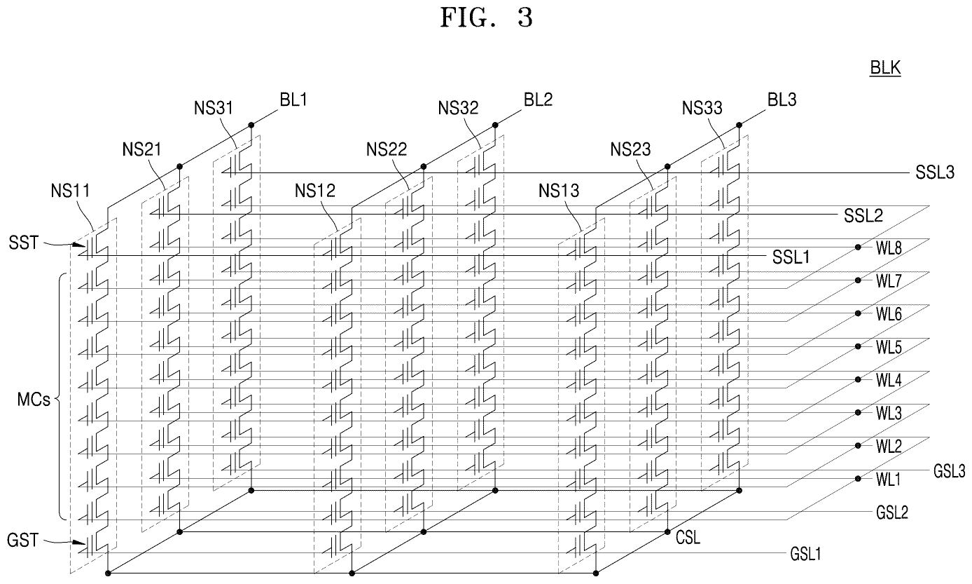

FIG. 3 is a circuit diagram illustrating a memory block BLK according to one or more implementations.

Referring to FIG. 3, the memory block BLK includes NAND strings NS11 to NS33, and each NAND string (e.g., NS11) may include a string selection transistor SST, a plurality of memory cells MC, and a ground selection transistor GST connected in series. The string selection transistor SST, the ground selection transistor GST, and the memory cells MC included in each NAND string may form a stack structure in a vertical direction on a substrate. For simplicity of the drawing, FIG. 3 shows that each of the plurality of memory NAND strings NS11 to NS33 includes eight memory cells MC, but the present disclosure is not limited thereto.

Bit lines BL1 to BL3 may extend in a first direction, and word lines WL1 to WL8 may extend in a second direction. The NAND strings NS11, NS21, and NS31 may be located between the first bit line BL1 and a common source line CSL, the NAND strings NS12, NS22, and NS32 may be located between the second bit line BL2 and the common source line CSL, and the NAND strings NS13, NS23, and NS33 may be located between the third bit line BL3 and the common source line CSL.

The string selection transistor SST may be connected to corresponding string selection lines SSL1 to SSL3. The memory cells MC may be connected to the corresponding word lines WL1 to WL8, respectively. The ground selection transistor GST may be connected to corresponding ground selection lines GSL1 to GSL3. The string selection transistor SST may be connected to a corresponding bit line, and the ground selection transistor GST may be connected to the common source line CSL. Here, the number of NAND strings, the number of word lines, the number of bit lines, the number of ground selection lines, and the number of string selection lines may be variously changed according to implementations.

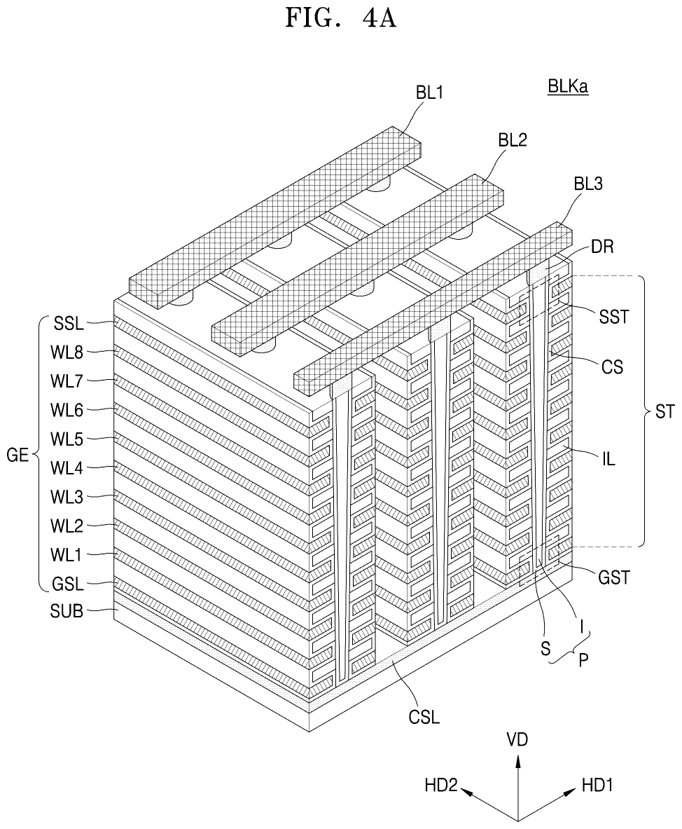

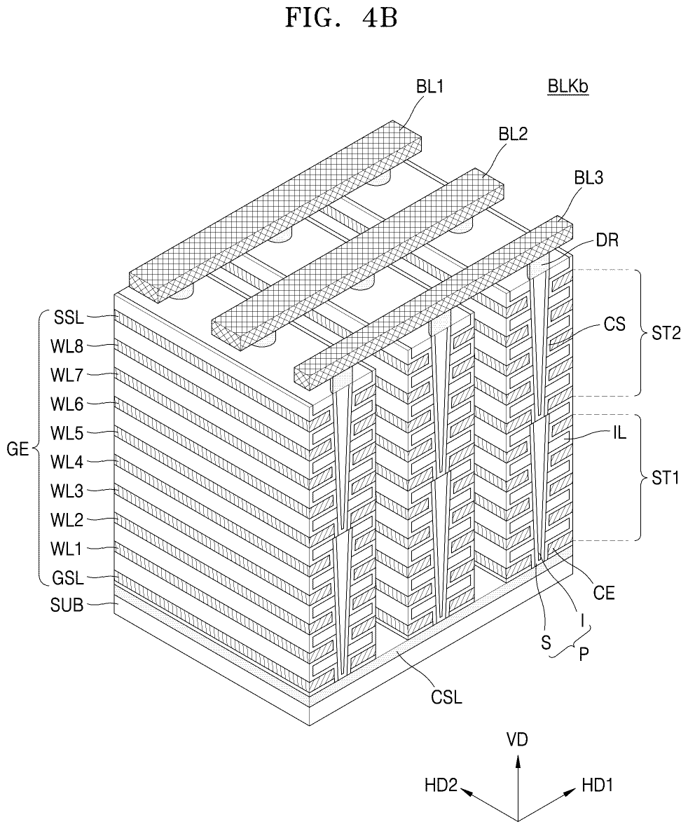

FIG. 4A is a perspective view illustrating a memory block BLKa according to one or more implementations. Referring to FIG. 4A, the memory block BLKa may correspond to one of the plurality of memory blocks BLK1 to BLKz in FIG. 2. The memory block BLKa may be formed in a vertical direction VD with respect to a substrate SUB.

The substrate SUB has a first conductivity type (e.g., a p-type) and extends in a second horizontal direction or a second direction HD2 on the substrate SUB. In some implementations, the common source line CLS doped with impurities of a second conductivity type (e.g., n-type) may be provided to the substrate SUB. In some implementations, the substrate SUB may be implemented as polysilicon, and the flat type common source line CSL may be disposed on the substrate SUB. On the substrate SUB, a plurality of insulating layers ILs extending in the second direction HD2 are sequentially provided in the vertical direction VD, and are spaced apart by a specific distance in the vertical direction VD. For example, the plurality of insulating layers ILs may include an insulating material such as silicon oxide.

A plurality of pillars P sequentially disposed in a first horizontal direction or a first direction HD1 and penetrating the plurality of insulating layers ILs in the vertical direction VD are provided on the substrate SUB. For example, the plurality of pillars P may penetrate the plurality of insulating layers ILs to be in contact with the substrate SUB. Specifically, a surface layer S of each pillar P may include a silicon material having a first type and may function as a channel area. Accordingly, in some implementations, the pillar P may be referred to as a channel structure or a vertical channel structure. Meanwhile, an inner layer I of each pillar P may include an insulating material such as silicon oxide or an air gap.

A charge storage layer CS is provided along exposed surfaces of the insulating layers IL, the pillars P, and the substrate SUB. The charge storage layer CS may include a gate insulating layer (or referred to as a tunneling insulating layer), a charge trap layer, and a blocking insulating layer. For example, the charge storage layer CS may have an oxide-nitride-oxide (ONO) structure. In addition, gate electrodes GE such as the ground selection lines GSL, the word lines WL1 to WL8, and the string selection lines SSL are provided on an exposed surface of the charge storage layer CS. The number of the ground selection line GSL, the word lines WL1 to WL8, and the string selection line SSL may be variously changed according to implementations.

Drain contacts or drains DR are respectively provided on the plurality of pillars P. For example, the drains DR may each include a silicon material doped with impurities having a second conductivity type. The bit lines BL1 to BL3 extending in the first direction HD1 and spaced apart by a specific distance in the second direction HD2 are provided on the drains DR.

FIG. 4B is a perspective view illustrating a memory block BLKb according to one or more implementations. In FIG. 4B, the memory block BLKb may correspond to one of the plurality of memory blocks BLK1 to BLKz in FIG. 2. In addition, the memory block BLKb corresponds to a modified example of the memory block BLKa of FIG. 4A, and a description given above with reference to FIG. 4A may also be applied to the present implementation.

The memory block BLKb may be formed in a direction perpendicular to the substrate SUB. The memory block BLKb may include a first memory stack ST1 and a second memory stack ST2 stacked in the vertical direction VD. The first memory stack ST1 is connected to the common source line CSL, the second memory stack ST2 is connected to the bit lines BL1 to BL3, and the first memory stack ST1 and the second memory stack ST2 are stacked to share a channel hole with each other. However, the present disclosure is not limited thereto, and the memory block BLKb may include three or more memory stacks.

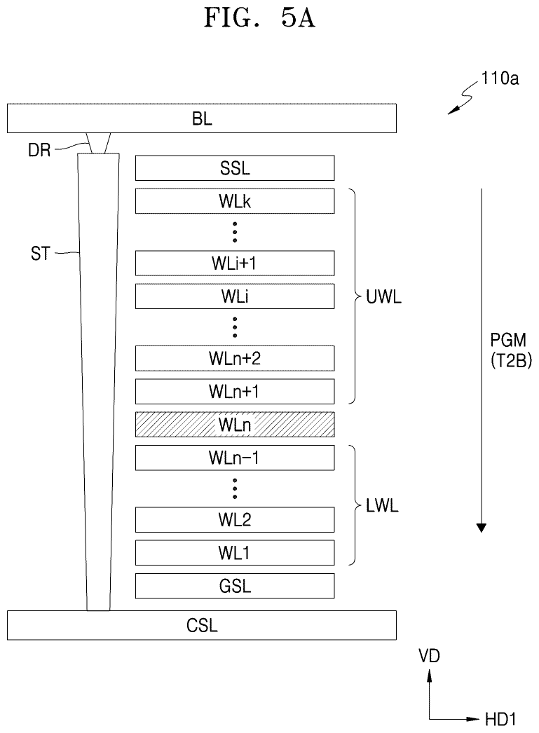

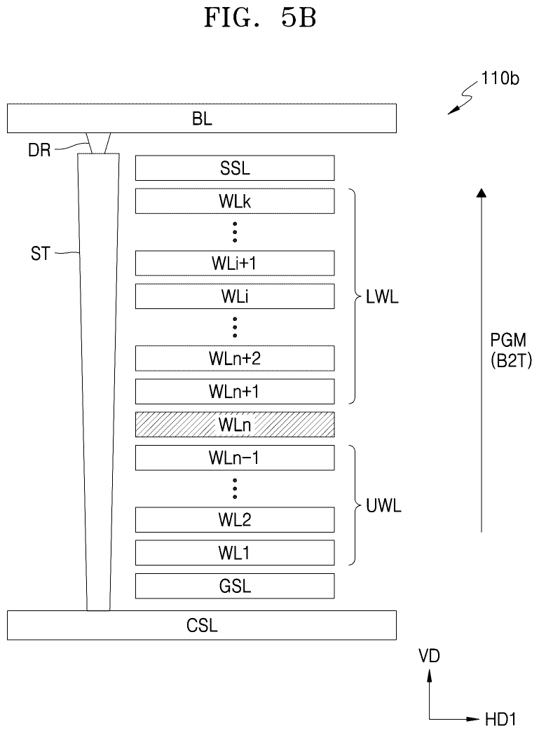

FIG. 5A schematically illustrates a memory cell array 110a according to one or more implementations.

Referring to FIG. 5A, the memory cell array 110a may include the common source line CSL and the bit line BL extending in the first direction HD1, and may include a memory stack ST extending in the vertical direction VD. In this regard, the memory stack ST may be connected to the bit line BL through the drain DR. For example, the memory cell array 110a may correspond to an example of FIG. 4A, and the memory stack ST may correspond to the first cell string NS11 of FIG. 3. In some implementations, a recovery operation may be performed in a direction from the bit line BL to the common source line CSL, but is not limited thereto. The recovery operation may be performed in a direction from the common source line CSL to the bit line BL, or may be performed in both directions.

The memory cell array 110a may further include a plurality of word lines WL1 to WLk stacked in the vertical direction VD, the ground selection line GSL may be disposed between the common source line CSL and the word line WL1, the string selection line SSL may be disposed between the bit line BL and the word line WLk, and k may be a positive integer. Although not shown, an upper GIDL erase control line may be further disposed between the string selection line SSL and the bit line BL, or a lower GIDL erase control line may be further disposed between the ground selection line GSL and the common source line CLS.

For example, a program operation may be performed in a direction from the word line WLk relatively close to the bit line BL to the word line WL1 relatively close to the common source line CSL. That is, the program operation may be performed according to a top-to-bottom (T2B) program sequence. Herein, a word line on which the program operation is performed prior to a selected word line WLn may be referred to as an upper word line UWL. For example, in FIG. 5A, the upper word line UWL may be one of a word line WLn+1 to the word line WLk, and may be above the selected word line WLn. The program operation is performed from the word line WLk, and thus, the word line WLk may be referred to as the uppermost word line.

A lower word line LWL may refer to a word line on which the program operation is performed after the selected word line WLn. For example, in FIG. 5A, the lower word line LWL may refer to one of the word line WL1 to a word line WLn−1, and may be below the selected word line WLn.

The plurality of word lines WL1 to WLk may be divided into pre word lines and post word lines. Some of the plurality of word lines WL1 to WLk may be pre word lines, and word lines among the plurality of word lines WL1 to WLk which are the pre word lines may be post word lines. The plurality of word lines WL1 to WLk may be grouped according to the recovery operation.

FIG. 5B schematically illustrates a memory cell array 110b according to one or more implementations. The memory cell array 110b of FIG. 5B may have a program direction different from that of the memory cell array 110a of FIG. 5A. Redundant descriptions with those given with reference to FIG. 5A are omitted.

The memory cell array 110b may be programmed from a word line far from the bit line BL to a word line close to the bit line BL. That is, a program operation may be performed according to a bottom to top (B2T) program sequence. In FIG. 5B, it is assumed that a selected word line is the word line WLn. For example, in FIG. 5B, the upper word line UWL may be one of the word line WL1 to the word line WLn−1, and may be below the selected word line WLn. The program operation is performed from the word line WL1, and thus, the word line WL1 may be referred to as the uppermost word line. For example, in FIG. 5B, the lower word line LWL may refer to one of the word line WLn+1 to the word line WLk, and may be above the selected word line WLn.

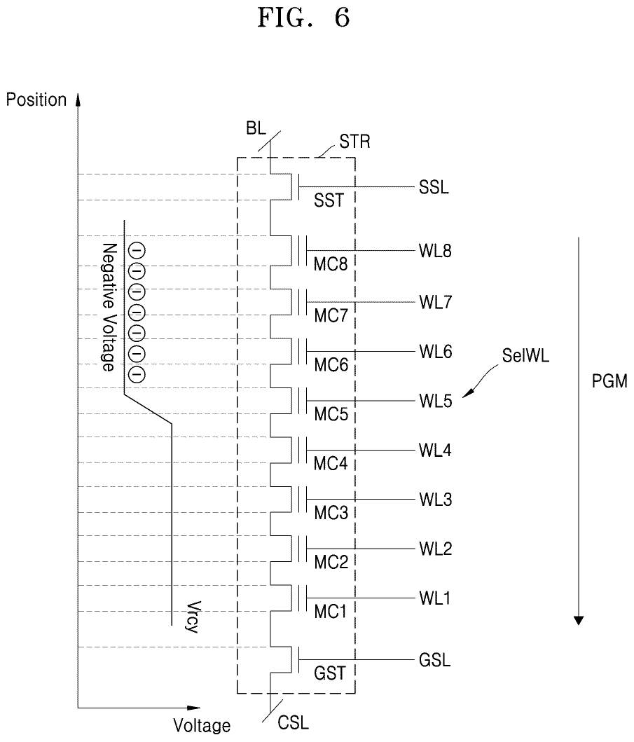

FIG. 6 is a voltage potential graph for each memory cell for explaining a program disturbance phenomenon.

Referring to FIG. 6, the bit line BL may be connected to a cell string STR including the string selection transistor SST, first to eighth memory cells MC1 to MC8, and the ground selection transistor GST. The bit line BL may be a selected bit line or an unselected bit line according to a state of the string selection transistor SST. Specifically, when the bit line BL is a selected bit line, the string selection transistor SST may be in an ON state, and when the bit line BL is an unselected bit line, the string selection transistor SST may be in an OFF state.

The first to eighth memory cells MC1 to MC8 may be connected to corresponding the first to eighth word lines WL1 to WL8, respectively, and each channel may have a certain voltage potential. FIG. 6 shows the voltage potential graph at a time when a verify period is completed during a program operation on a memory cell connected to the fifth word line WL5. The fifth word line WL5 may be a selected word line SelWL.

The program operation may be sequentially performed from an upper word line. For example, it is assumed that the program operation is sequentially performed from the eighth word line WL8 to the first word line WL1. The program operation is sequentially performed from the eighth word line WL8 to the first word line WL1, and thus, when the fifth word line WL5 is the selected word line SelWL for the program operation, the program operation on the sixth to eighth word lines WL6 to WL8 may be completed. For example, in FIG. 5, the upper word line may refer to one of the sixth to eighth word lines WL6 to WL8, and may be above the selected word line SelWL. For example, in FIG. 5, a lower word line may refer to one of the first to fifth word lines WL1 to WL5, and may be below the selected word line SelWL. The upper word line is post-programmed and may be in a program state, and the lower word line and the selected word line SelWL are pre-programmed and may be in an erase state.

When a memory device performs a recovery operation after a verify period, the memory device may discharge voltages of the first to eighth word lines WL1 to WL8 from a program verification voltage and a read voltage to a recovery voltage Vrcy. For example, the recovery voltage Vrcy may be a ground voltage GND, but is not limited thereto. As voltages are discharged to the recovery voltage, charges of the first to eighth word lines WL1 to WL8 may be negatively down-coupled, which is called negative boosting or under-coupling. Consequently, a period between the upper word lines WL6 to WL8 may have a negative voltage by negative boosting.

A channel corresponding to first to fourth memory cells MC1 to MC4 connected to the lower word lines WL1 to WL4 may have the recovery voltage Vrcy according to the recovery voltage Vrcy. Therefore, a voltage level difference between the negative voltages of the sixth to eighth memory cells MC6 to MC8 and the recovery voltage Vrcy of the first to fifth memory cells MC1 to MC5 may increase. That is, as the voltage level difference between a memory cell corresponding to the selected word line SelWL and a memory cell adjacent thereto increases, memory cells in the erase state may be programmed to the lower word lines WL1 to WL4 other than the selected word line SelWL by band-to-band tunneling (BTBT) or hat carrier injection (HCI). That is, a program disturbance may be induced. As a read voltage increases, and the number of times of program and read are repeated, the program disturbance may increase. A sequential recovery operation may be performed to suppress the program disturbance.

FIG. 7 is a diagram for explaining an Nth program loop Loop(N) and an N+1 program loop Loop(N+1) according to one or more implementations. FIG. 7 is a diagram illustrating that the second recovery period RCY2 starts after a setup operation for activating string selection lines starts in the bit line setup period BL_SETUP.

Referring to FIG. 7, each program loop may include one or more periods. For example, each program loop may include the bit line setup period BL_SETUP, the program execution period PGM_EXE, the verify period VFYNOM, and the recovery period RCY. The bit line setup period BL_SETUP, the program execution period PGM_EXE, the verify period VFYNOM, and the recovery period RCY may be repeated for each loop.

The recovery period RCY of the Nth program loop Loop(N) and the bit line setup period BL_SETUP of the N+1 program loop Loop(N+1) may be included between the verify period VFYNOM of the Nth program loop Loop(N) and the program execution period PGM_EXE of the N+1 program loop Loop(N+1). A sequential recovery operation may be performed in the recovery period RCY of the Nth program loop Loop(N). In the recovery period RCY, the memory device (e.g., 100 of FIG. 1) may sequentially perform a recovery operation on a plurality of word lines. The memory device 100 may group a plurality of word lines into two or more groups and apply a recovery voltage to each group at different times. The sequential recovery operation is performed, and thus, a voltage level difference between a memory cell corresponding to a selected word line and a memory cell adjacent thereto may be reduced, and negative boosting in a channel area may be suppressed, thereby reducing a program disturbance. When the setup operation in the bit line setup period BL_SETUP starts after recovery of all word lines is completed by the sequential recovery operation in the recovery period RCY, a setup operation is performed after the recovery operation, and thus, the entire program time may be increased.

In some implementations, the setup operation of the bit line setup period BL_SETUP may start after the recovery operation on some word lines is completed. FIG. 7 shows that, after the recovery operation on some word lines is completed, the setup operation starts, and then the recovery operation on the remaining word lines is performed. The bit line setup period BL_SETUP starts after the recovery operation on some word lines is performed, and thus, the setup period may be performed while the recovery operation on at least some of the remaining word lines is performed, and the entire program time may be reduced.

Referring to FIG. 7, the recovery period RCY may include a first recovery period RCY1 and a second recovery period RCY2. The bit line setup period BL_SETUP may start in the middle of the recovery period RCY. The recovery voltage may be applied to a pre word line among the plurality of word lines in the first recovery period RCY1. The recovery voltage may be applied to a post word line among the plurality of word lines in the second recovery period RCY2. For example, the memory device (e.g., 100 of FIG. 1) may perform the sequential recovery operation of performing the recovery operation on different word lines in each of the first recovery period RCY1 and the second recovery period RCY2.

The bit line setup period BL_SETUP may follow the first recovery period RCY1. The memory device 100 may apply the recovery voltage to the pre word line in the first recovery period RCY1, and then start the setup operation of the bit line setup period BL_SETUP. FIG. 7 shows that the setup operation is performed after the first recovery period RCY1, the bit line setup period BL_SETUP follows the first recovery period RCY1, but the present disclosure is not limited thereto. The entire bit line setup period BL_SETUP may proceed simultaneously with the recovery period RCY.

In some implementations, the second recovery period RCY2 may start after the setup operation starts in the bit line setup period BL_SETUP. After the first recovery period RCY1, the second recovery period RCY2 may start after a specific time period sp. The setup operation of the bit line setup period BL_SETUP may start after the first recovery period RCY1, and the second recovery period RCY2 may start after the specific time period sp.

After the setup operation starts in the bit line setup period BL_SETUP of the N+1 program loop Loop(N+1), the second recovery period RCY2 of the Nth program loop Loop(N) may start. The setup operation of the bit line setup period BL_SETUP starts in the middle of the recovery period RCY, and thus, other operations in the bit line setup period BL_SETUP may be performed even while the second recovery operation is performed, and the entire program time may be reduced.

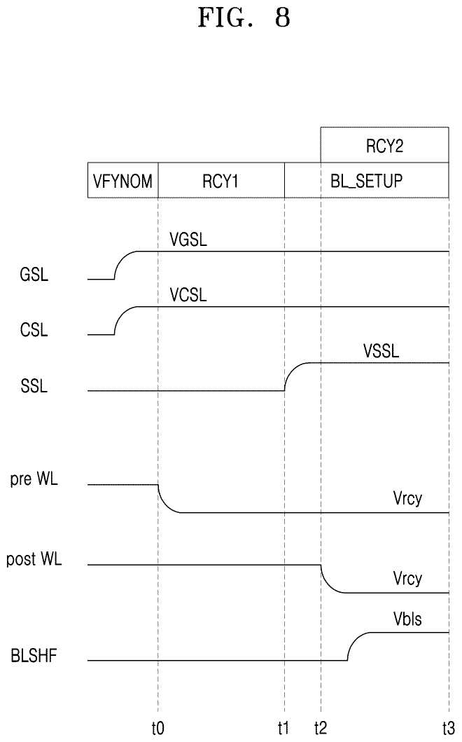

FIG. 8 is a timing diagram illustrating an operation of a memory device according to one or more implementations. FIG. 8 is the timing diagram corresponding to the Nth program loop Loop(N) and the N+1 program loop Loop(N+1) of FIG. 7. In FIG. 8, for simplicity of the drawing, a program execution period is omitted. Redundant descriptions with those given with reference to FIG. 7 are omitted.

Referring to FIG. 8, a setup operation of the bit line setup period BL_SETUP may start after the first recovery period RCY1, and then the second recovery period RCY2 may start. The verify period VFYNOM may be a time period before a first time t0, and a part of the verify period VFYNOM is shown in FIG. 8. The ground selection line voltage VGSL may be applied to the ground selection line GSL before the first recovery period RCY1. For example, the ground selection line voltage VGSL may be applied to the ground selection line GSL in the verify period VFYNOM. The ground selection line voltage VGSL may correspond to a voltage level at which the ground selection transistor (e.g., GST of FIG. 3) is turned on. For example, the ground selection line voltage VGSL may be maintained in the first recovery period RCY1 and the bit line setup period BL_SETUP.

A common source line voltage VCSL may be applied to the common source line CSL before the first recovery period RCY1. For example, the common source line voltage VCSL may be applied to the common source line CSL in the verify period VFYNOM. For example, the common source line voltage VCSL may be maintained in the first recovery period RCY1 and the bit line setup period BL_SETUP.

The first recovery period RCY1 may correspond to a time period from the first time t0 to a second time t1, and in the first recovery period RCY1, a voltage of the pre word line preWL may decrease to a level of the recovery voltage Vrcy. The pre word line preWL may be recovered in the first recovery period RCY1. For example, the recovery voltage Vrcy applied to the pre word line preWL may be maintained up to the bit line setup period BL_SETUP. For example, the pre word line preWL may be one of the word line WLn+1 to the word line WLk of FIG. 5A, but this is an example and is not necessarily limited thereto.

The bit line setup period BL_SETUP may correspond to a time period from the second time t1 to a fourth time t3, and the string selection line voltage VSSL may be applied to the string selection line SSL. The string selection line voltage VSSL may correspond to a voltage level at which the string selection transistor (e.g., SST of FIG. 3) is turned on. In some implementations, the string selection line voltage VSSL may be maintained during the second recovery period RCY2. FIG. 8 shows that a setup operation in which the string selection line SSL is activated is performed after the first recovery period RCY1, the bit line setup period BL_SETUP follows the first recovery period RCY1, but the present disclosure is not necessarily limited thereto, and other operations in the bit line setup period BL_SETUP may be performed to overlap the first recovery period RCY1.

In the bit line setup period BL_SETUP, a bit line shut-off signal BLSHF may increase to a level of a bit line shut-off voltage Vbls. The bit line shut-off signal BLSHF may drive a bit line shut-off transistor included in the page buffer circuit (e.g., 130 of FIG. 2). The bit line shut-off transistor may be connected to the bit line (e.g., BL of FIG. 2). When the bit line shut-off transistor is turned on, the page buffer circuit 130 may be connected to the bit line BL. For example, after the string selection line voltage VSSL is applied to the string selection line SSL, the bit line shut-off signal BLSHF may increase to the level of the bit line shut-off voltage Vbls.

The second recovery period RCY2 may correspond to a time period from a third time t2 to a fourth time t3. After the second time t1 which is a start time of the bit line setup period BL_SETUP, the second recovery period RCY2 may start from the third time t2. After the string selection line voltage VSSL is applied to the string selection line SSL, a voltage of a post word line voltage postWL may decrease to the level of the recovery voltage Vrcy in the second recovery period RCY2. The post word line postWL may be recovered in the second recovery period RCY2. In the second recovery period RCY2, a second recovery operation and a bit line setup operation may be performed in parallel. For example, the post word line postWL may be one of the word line WL1 to the word line WLn of FIG. 5A, but this is an example and is not necessarily limited thereto.

A memory device may perform the recovery operation on the pre word line preWL in the first recovery period RCY1 and the recovery operation on the post word line postWL in the second recovery period RCY2, and thus, the memory device may perform a sequential recovery operation. In addition, after performing the first recovery operation, the memory device may perform the setup operation of applying the string selection line voltage VSSL to the string selection line SSL, and then perform the second recovery operation.

FIG. 8 shows that the recovery voltage Vrcy is simultaneously applied to the pre word lines preWL in the first recovery period RCY1, but the present disclosure is not limited thereto, and the first recovery operation may be sequentially performed in the first recovery period RCY1. For example, the pre word lines preWL may be grouped into two or more groups, and the recovery voltage Vrcy may be applied to each group at different times. In addition, FIG. 8 shows that the recovery voltage Vrcy is simultaneously applied to the post word lines postWL in the second recovery period RCY2, but the present disclosure is not limited thereto, and the second recovery operation may be performed sequentially in the second recovery period RCY2. For example, the post word lines postWL may be grouped into two or more groups, and the recovery voltage Vrcy may be applied to each group at different times.

FIG. 9 is a timing diagram illustrating an operation of a memory device according to one or more implementations. In FIG. 9, it is assumed that the pre word lines preWL are the word line WLn+1 of FIG. 5A and a word line WLn+2. In FIG. 9, a ground source line, a common source line, and a bit line shut-off signal are omitted for simplicity of the drawing. Redundant descriptions with those given with reference to FIG. 9 are omitted. Hereinafter, FIGS. 5A and 9 are referred to together.

After the first recovery period RCY1, a setup operation of the bit line setup period BL_SETUP may start, and then the second recovery period RCY2 may start. After the second recovery period RCY2, the program execution period PGM_EXE may start. The pre word line preWL may be recovered in the first recovery period RCY1. The pre word line preWL may be one word line or two or more word lines.

In some implementations, the control logic (e.g., 120 of FIG. 1) may recover at least two or more of the plurality of word lines WL1 to WLk in the first recovery period RCY1. At least two of the plurality of word lines WL1 to WLk may be the pre word lines preWL. In some implementations, the control logic 120 may simultaneously apply the recovery voltage Vrcy to at least two word lines. For example, the control logic 120 may simultaneously apply the recovery voltage Vrcy to the two or more pre word lines preWL. For example, the control logic 120 may simultaneously apply the recovery voltage Vrcy to the word line WLn+1 and the word line WLn+2. However, the present disclosure is not necessarily limited thereto, and the control logic 120 may sequentially apply the recovery voltage Vrcy to the two or more pre word lines preWL.

In some implementations, the control logic 120 may apply the recovery voltage Vrcy to at least some of the upper word lines UWL in the first recovery period RCY1. The pre word lines preWL may be at least some of the upper word lines UWL. A first recovery operation may be performed on at least some of the upper word lines UW on which a program operation is performed prior to the selected word line WLn, prior to the setup operation in the bit line setup period BL_SETUP. For example, the pre word lines preWL may be the word line WLn+1 and the word line WLn+2. However, the present disclosure is not limited thereto, and the pre word lines preWL may include at least two upper word lines UWL. The first recovery operation is performed on at least some of the upper word lines UW, and thus, a short of a cell string may be reduced.

In the bit line setup period BL_SETUP, the string selection line voltage VSSL may be applied to the string selection line SSL. In the bit line setup period BL_SETUP, the recovery voltage Vrcy may be continuously applied to the pre word line preWL.

In the second recovery period RCY2, a voltage of the post word line postWL may decrease to a level of the recovery voltage Vrcy. The control logic 120 may recover the post word line postWL in the second recovery period RCY2. The post word line postWL may be a word line other than the pre word line preWL among the plurality of word lines WL1 to WLk. The post word line postWL may be a word line on which the first recovery operation is not performed. According to the pre word line preWL, the post word line postWL may include at least one of the upper word line UWL, the selected word line WLn, or the lower word line LWL. For example, the post word line postWL may include the word line WL1 to the select word line WLn and a word line WLn+3 to the word line WLk. However, the present disclosure is not necessarily limited thereto.

In some implementations, the control logic 120 may simultaneously apply the recovery voltage Vrcy to the post word lines postWL. For example, in the second recovery period RCY2, the control logic 120 may simultaneously apply the recovery voltage Vrcy to the word line WL1 to the selected word line WLn and the word line WLn+3 to the word line WLk. However, the present disclosure is not necessarily limited thereto, and the control logic 120 may sequentially apply the recovery voltage Vrcy to the post word line postWL. In the second recovery period RCY2, the recovery voltage Vrcy may be continuously applied to the pre word line preWL. In the second recovery period RCY2, the string selection line voltage VSSL may be continuously applied to the string selection line SSL.

The program execution period PGM_EXE may correspond to the fourth time t3 to the fifth time t4. In the program execution period PGM_EXE, the string selection line voltage VSSL may be continuously applied to a selected string selection line, and the ground voltage GND may be applied to an unselected string selection line. In the program execution period PGM_EXE, a pass voltage Vpass may be applied to unselected word lines. For example, the pass voltage Vpass may be applied to the word line WLn+1 and the word line WLn+2, which are the pre word lines preWL, and the pass voltage Vpass may be applied to the word lines WL1 to WLn−1 and the word lines WLn+3 to WLk among the post word lines postWL. In the program execution period PGM_EXE, a program voltage Vpgm may be applied to the selected word line WLn. For example, a voltage level of the program voltage Vpgm may higher than that of the pass voltage Vpass.

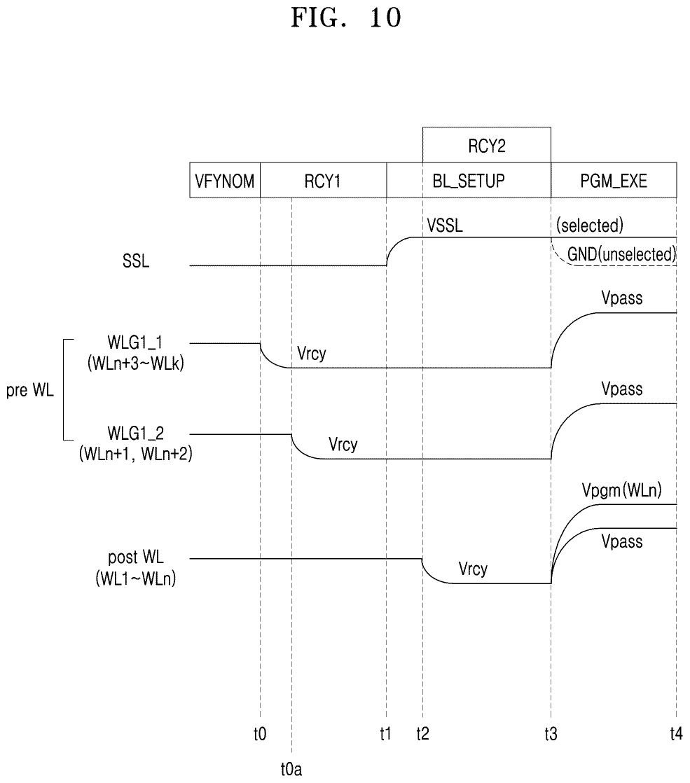

FIG. 10 is a timing diagram for explaining a first recovery operation according to one or more implementations. FIG. 10 shows that the first recovery operation is sequentially performed on the pre word lines preWL. In FIG. 10, it is assumed that the pre word lines preWL are the word line WLn+1 to the word line WLk of FIG. 5A. Redundant descriptions with those given above are omitted. Hereinafter, FIGS. 5A and 10 are referred to together.

The control logic 120 may sequentially perform the first recovery operation on the pre word lines preWL in the first recovery period RCY1. Some of the plurality of word lines WL1 to WLK may be grouped into a first word line group WLG1 including at least one word line. The pre word lines preWL may be grouped into the first word line group WLG1 including at least one word line. In some implementations, in the first recovery period RCY1, the control logic 120 may apply the recovery voltage Vrcy to the first word line group WLG1 at different times for each first word line group WLG1. For example, the pre word lines preWL may be grouped into two first word line groups WLG1. The pre word lines preWL may be grouped into a first word line group WLG1_1 and a first word line group WLG1_2. However, the present disclosure is not limited thereto, and the pre word lines preWL may be grouped into three or more first word line groups WLG1.

In some implementations, the pre word lines preWL may be grouped into the first word line group WLG1 based on the order in which a program operation is performed. The program operation may be performed in the order of the word line WLk to the word line WL1, and may be grouped into the first word line group WLG1 according to the order in which the program operation is performed. For example, the first word line group WLG1_1 may include the word lines WLn+3 to WLk, and the first word line group WLG1_2 may include the word lines WLn+1 and WLn+2. The word lines WLn+3 to WLk included in the first word line group WLG1_1 may be word lines on which the program operation is performed prior to the word lines WLn+1 and WLn+2 included in the first word line group WLG1_2. However, the present disclosure is not necessarily limited thereto, and the word lines included in the first word line group WLG1 may be variously grouped.

The control logic 120 may perform the first recovery operation on the first word line group WLG1_1 and then perform the first recovery operation on the first word line group WLG1_2. The control logic 120 may apply the recovery voltage Vrcy to the pre word lines preWL included in the first word line group WLG1_1, and then apply the recovery voltage Vrcy to the pre word lines preWL included in the first word line group WLG1_2. For example, the recovery voltage Vrcy may be applied to the pre word lines preWL included in the first word line group WLG1_1 at the first time t0, and the recovery voltage Vrcy may be applied to the pre word lines preWL included in the first word line group WLG1_2 at a time t0a. The time t0a may be a time between the first time t0 and the second time t1.

In some implementations, in the first recovery period RCY1, the recovery voltage Vrcy may be applied first to the first word line group WLG1 on which the program operation is performed first. The recovery voltage Vrcy may be sequentially applied to each of the first word line groups WLG1 in order of proximity to the uppermost word line WLk on which the program operation is performed first among the plurality of word lines WL1 to WLk. For example, the first word line group WLG1_1 includes the word lines WLn+3 to WLk, and thus, the first word line group WLG1_1 may be the first word line group WLG1 on which the program operation is performed before the first word line group WLG1_2, and may be closer to the uppermost word line WLk than the first word line group WLG1_2. After the recovery voltage Vrcy is applied to the first word line group WLG1_1 relatively close to the uppermost word line WLk, the recovery voltage Vrcy may be applied to the first word line group WLG1_2 relatively far from the uppermost word line WLk.

In the second recovery period RCY2, the control logic 120 may simultaneously apply the recovery voltage Vrcy to the post word line postWL. For example, in the second recovery period RCY2, the control logic 120 may simultaneously apply the recovery voltage Vrcy to the word line WL1 to the selected word line WLn.

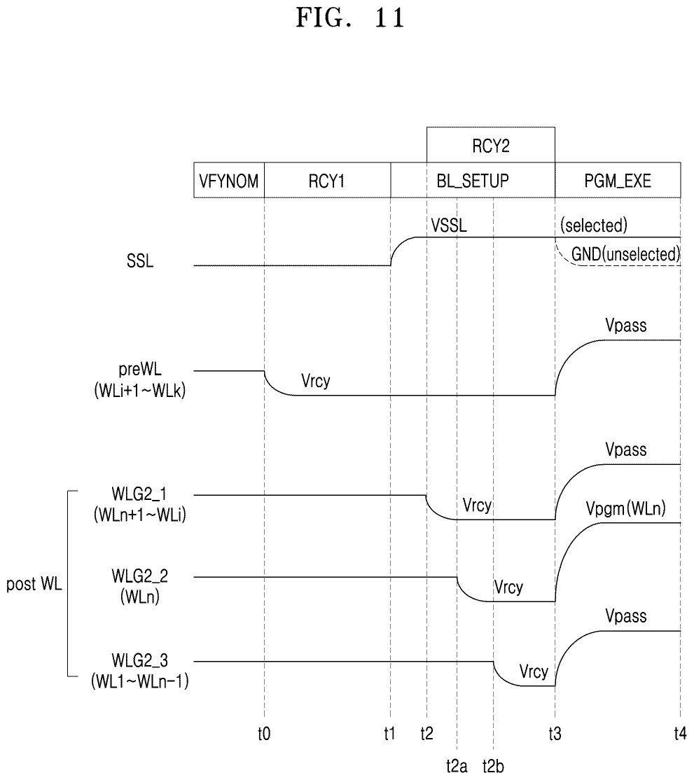

FIG. 11 is a timing diagram for explaining a second recovery operation according to one or more implementations. FIG. 11 shows that the second recovery operation is sequentially performed on the post word line postWL. FIG. 11 shows that it is assumed that the pre word lines preWL are the word line WLi+1 to the word line WLk of FIG. 5A, and that the pre word lines preWL are simultaneously recovered. Redundant descriptions with those given above are omitted. Hereinafter, FIGS. 5A and 11 are referred to together.

The control logic 120 may simultaneously recover the pre word lines preWL in the first recovery period RCY1. However, the present disclosure is not necessarily limited thereto.

In the second recovery period RCY2, the control logic (e.g., 120 of FIG. 1) may sequentially perform the second recovery operation. The post word lines postWL may be the word line WL1 to a word line WLi. The post word line postWL may be grouped into a second word line group WLG2 including at least one word line. In some implementations, in the second recovery period RCY2, the control logic 120 may apply the recovery voltage Vrcy to the second word line group WLG2 at different times for each second word line group WLG2. For example, the post word line postWL may be grouped into three second word line groups WLG2. The post word lines postWL may be grouped into a second word line group WLG2_1, a second word line group WLG2_2, and a second word line group WLG2_3. However, the present disclosure is not limited thereto, and the post word lines postWL may be grouped into various numbers of second word line groups WLG2.

In some implementations, the post word lines postWL may be grouped into the second word line group WLG2 based on the order in which a program operation is performed. For example, the second word line group WLG2_1 may include the word lines WLn+1 to WLi, the second word line group WLG2_2 may include the word line WLn, and the second word line group WLG2_3 may include the word lines WL1 to WLn-1. The second word line group WLG2_1 may perform the program operation before the second word line group WLG2_2, and the second word line group WLG2_2 may perform the program operation before the second word line group WLG2_3. However, the present disclosure is not necessarily limited thereto, and word lines included in the second word line group WLG2 may be variously grouped.

After performing the second recovery operation on the second word line group WLG2_1, the control logic 120 may perform the second recovery operation on the second word line group WLG2_2, and then perform the second recovery operation on the second word line group WLG2_3. For example, the recovery voltage Vrcy may be applied to the post word lines postWL included in the second word line group WLG2_1 at the third time t2, the recovery voltage Vrcy may be applied to the post word lines postWL included in the second word line group WLG2_2 at a time t2a, and the recovery voltage Vrcy may be applied to the post word lines postWL included in the second word line group WLG2_3 at a time t2b. The time t2a and the time t2b may be times between the third time t2 and the fourth time t3, and the time t2a may precede the time t2b.

In some implementations, in the second recovery period RCY2, the recovery voltage Vrcy may be applied first to the second word line group WLG2 on which the program operation is performed first. The recovery voltage Vrcy may be sequentially applied to each of the second word line groups WLG2 in order of proximity to the uppermost word line WLk. For example, the recovery voltage Vrcy may be first applied to the second word line group WLG2_1 relatively close to the uppermost word line WLk, and the recovery voltage Vrcy may be applied in order of the second word line group WLG2_2 and the second word line group WLG2_3.

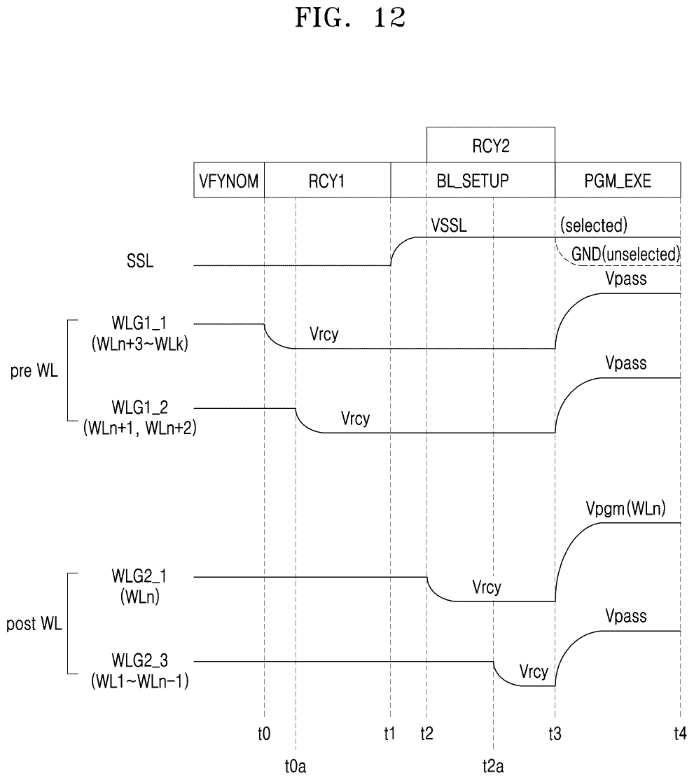

FIG. 12 is a timing diagram for explaining a first recovery operation and a second recovery operation according to one or more implementations. FIG. 12 shows that a recovery operation is sequentially performed on the pre word line preWL and the post word line postWL. In FIG. 12, it is assumed that the pre word lines preWL are the word line WLn+1 to the word line WLk of FIG. 5A. Redundant descriptions with those given above are omitted. Hereinafter, FIGS. 5A and 12 are referred to together.

In the first recovery period RCY1, the control logic (e.g., 120 of FIG. 1) may sequentially perform the first recovery operation. For example, the recovery voltage Vrcy may be applied to the word lines WLk to WLn+3 included in the first word line group WLG1_1 at the first time t0, and the recovery voltage Vrcy may be applied to the word lines WLn+1 and WLn+2 included in the first word line group WLG1_2 at the time t0a.

At the second time t1 after the first time t0, the bit line setup period BL_SETUP may start. The second recovery period RCY2 may start from the third time t2. In the second recovery period RCY2, the control logic 120 may sequentially perform the second recovery operation. For example, the recovery voltage Vrcy may be applied to the word line WLn included in the second word line group WLG2_1 at the third time t2, and the recovery voltage Vrcy may be applied to the word lines WL1 to WLn−1 included in the second word line group WLG2_2 at the time t2a. In FIG. 12, the grouped first word line group WLG1 and second word line group WLG2 correspond to examples, but the present disclosure is not necessarily limited thereto.

In addition, FIG. 12 shows that the same recovery voltage Vrcy is applied to the pre word line preWL and the post word line postWL, but the present disclosure is not necessarily limited thereto, and different recovery voltages may be applied to the pre word line preWL and the post word line postWL. In addition, the recovery voltage may be different for each first word line groups WLG1, and the recovery voltage may be different for each second word line groups WLG2.

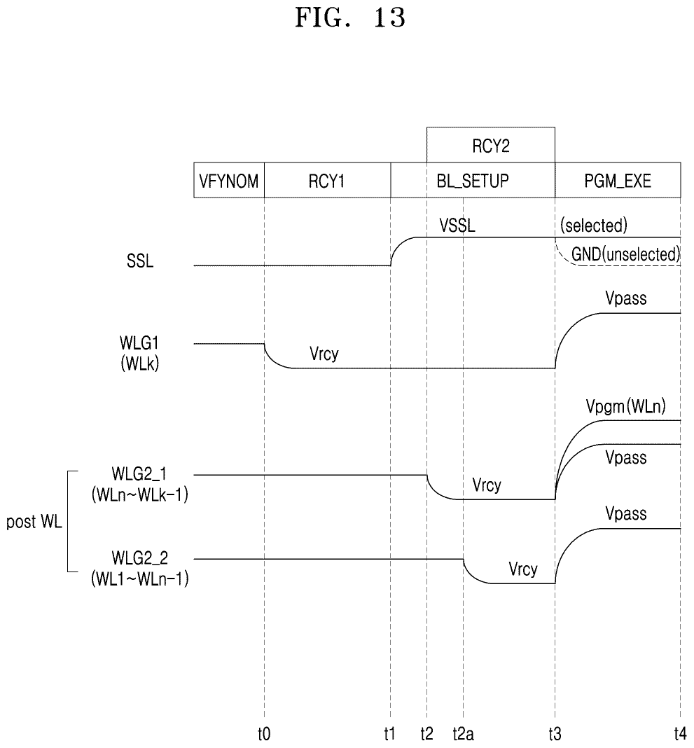

FIG. 13 is a timing diagram for explaining performing a first recovery operation on the uppermost word line WLk according to one or more implementations. Redundant descriptions with those given above are omitted. Hereinafter, FIGS. 5A and 11 are referred to together.

In some implementations, in the first recovery period RCY1, the recovery voltage Vrcy may be applied to the uppermost word line group including the uppermost word line WLk. In the first recovery period RCY1, the first recovery operation may be performed only on the first word line group WLG1 including the uppermost word line WLk. For example, when only the uppermost word line WLk is a pre word line, the first word line group WLG1 may include the uppermost word line WLk, and the control logic 120 may apply the recovery voltage Vrcy to the uppermost word line WLk. However, the present disclosure is not necessarily limited thereto. For example, the recovery voltage Vrcy may be applied to the first word line group WLG1 including the uppermost word line WLk and other pre word lines.

In the second recovery period RCY2, the recovery voltage Vrcy may be applied to the word lines WLn to WLk−1 included in the second word line group WLG2_1 at the third time t2, and the recovery voltage Vrcy may be applied to the word lines WL1 to WLn−1 included in the second word line group WLG2_2 at the time t2a. In FIG. 13, the grouped first word line group WLG1 and second word line group WLG2 correspond to examples, but the present disclosure is not necessarily limited thereto.

FIG. 14 is a diagram for explaining the bit line setup period BL_SETUP and the second recovery period RCY2 according to one or more implementations. In comparison with FIG. 7, FIG. 14 shows that a setup operation of the bit line setup period BL_SETUP and the second recovery period RCY2 start simultaneously. Redundant descriptions with those given with reference to FIG. 7 are omitted.

Referring to FIG. 14, the recovery period RCY may include the first recovery period RCY1 and the second recovery period RCY2. The setup operation of the bit line setup period BL_SETUP may start in the middle of the recovery period RCY. The setup operation of the bit line setup period BL_SETUP may be performed after the first recovery period RCY1. After applying a recovery voltage to a pre word line in the first recovery period RCY1, the memory device 100 may start the setup operation of the bit line setup period BL_SETUP.

In some implementations, the second recovery operation may start simultaneously with the setup operation of applying a string selection line voltage to string selection lines in the bit line setup period BL_SETUP. That is, after the first recovery period RCY1, the setup operation of the bit line setup period BL_SETUP and the second recovery period RCY2 may proceed together.

The bit line setup period BL_SETUP of the N+1 program loop Loop(N+1) and the second recovery period RCY2 of the Nth program loop Loop(N) may start in parallel. The setup operation of the bit line setup period BL_SETUP and the second recovery period RCY2 start simultaneously, and thus, a separate overhead may not be required for the setup operation, and the entire program time may be reduced, thereby improving the performance of the memory device (e.g., 100 of FIG. 1).

FIG. 15 is a timing diagram illustrating an operation of a memory device according to one or more implementations. FIG. 15 is the timing diagram corresponding to the N+1 program loop Loop(N+1) and the Nth program loop Loop(N) of FIG. 14. In comparison with FIG. 8, a setup operation of the bit line setup period BL_SETUP and the second recovery period RCY2 may start simultaneously. In FIG. 15, for simplicity of the drawing, a program execution period is omitted. Redundant descriptions with those given with reference to FIGS. 8 and 14 are omitted.

Referring to FIG. 15, the first recovery period RCY1 may correspond to a time period from the first time t0 to the second time t1. After the first recovery period RCY1, the setup operation of the bit line setup period BL_SETUP and the second recovery period RCY2 may start.

The bit line setup period BL_SETUP corresponds to a time period from the second time t1 to the third time t2, and the string selection line voltage VSSL may be applied to the string selection line SSL. For example, the setup operation of applying the string selection line voltage VSSL to the string selection line SSL at the second time t1 may start. The string selection line voltage VSSL may be maintained during the bit line setup period BL_SETUP. FIG. 15 shows that the setup operation is performed after the first recovery period RCY1, and the bit line setup period BL_SETUP follows the first recovery period RCY1, but the present disclosure is not necessarily limited thereto, and other operations in the bit line setup period BL_SETUP may be performed to overlap the first recovery period RCY1.

The second recovery period RCY2 may correspond to a time period from the second time t1 to the third time t2. The second recovery period RCY2 may start from the second time t1. The string selection line voltage VSSL may be applied to the string selection line SSL, and simultaneously, a voltage of the post word line postWL may decrease to a level of the recovery voltage Vrcy in the second recovery period RCY2. The second recovery operation on the post word line postWL may start from the second time t1.

FIG. 15 shows that the recovery voltage Vrcy is simultaneously applied to the pre word lines preWL in the first recovery period RCY1, but the present disclosure is not necessarily limited thereto, and the first recovery operation may be sequentially performed in the first recovery period RCY1. For example, the pre word lines preWL may be grouped into two or more groups, and a recovery voltage may be applied to each group at different times. In addition, FIG. 15 shows that the recovery voltage Vrcy is simultaneously applied to the post word lines postWL in the second recovery period RCY2, but the present disclosure is not necessarily limited thereto, and the second recovery operation may be performed sequentially in the second recovery period RCY2. For example, the post word lines postWL may be grouped into two or more groups, and the recovery voltage may be applied to each group at different times. The descriptions of FIGS. 9 to 13 are also applicable to the operation of the memory device of FIG. 15.

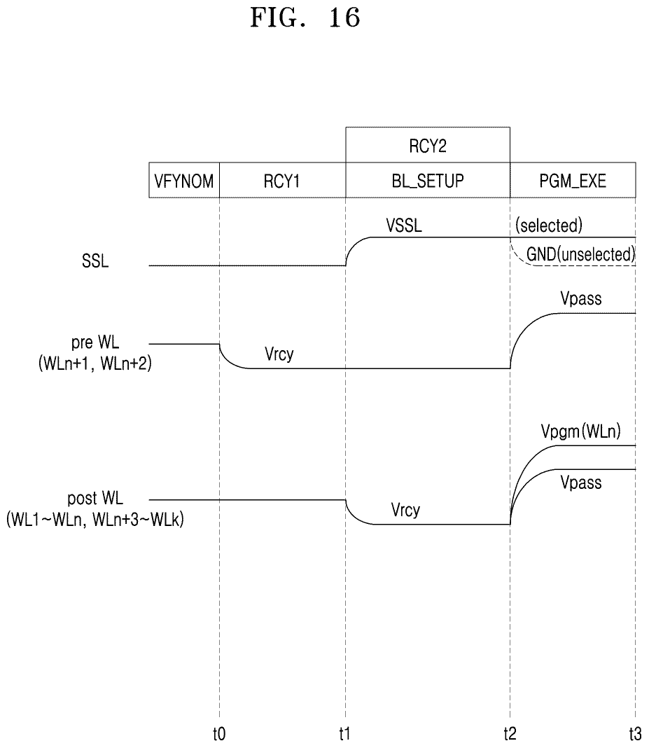

FIG. 16 is a timing diagram illustrating an operation of a memory device according to one or more implementations. In FIG. 16, it is assumed that the pre word line presWL are the word line WLn+1 and the word line WLn+2 of FIG. 5A. In comparison with FIG. 9, the second recovery period RCY2 and a setup operation of the bit line setup period BL_SETUP may start simultaneously. Redundant descriptions with those given with reference to FIGS. 9 and 15 are omitted. Hereinafter, FIGS. 5A and 16 are referred to together.

In some implementations, the control logic 120 may simultaneously apply the recovery voltage Vrcy to at least two word lines. For example, the control logic 120 may simultaneously apply the recovery voltage Vrcy to the word line WLn+1 and the word line WLn+2. However, the present disclosure is not necessarily limited thereto, and the control logic 120 may sequentially apply the recovery voltage Vrcy to two or more pre word lines preWL.

In the bit line setup period BL_SETUP, the string selection line voltage VSSL may be applied to the string selection line SSL. In the bit line setup period BL_SETUP, the string selection line voltage VSSL may be applied to the string selection line SSL and simultaneously a second recovery operation may start.

In the second recovery period RCY2, a voltage of the post word line postWL may decrease to a level of the recovery voltage Vrcy. The control logic 120 may recover the post word line postWL in the second recovery period RCY2. In some implementations, the control logic 120 may simultaneously apply the recovery voltage Vrcy to at least two post word lines postWL. For example, in the second recovery period RCY2, the control logic 120 may simultaneously apply the recovery voltage Vrcy to the word line WL1 to the word line WLn and the word line WLn+3 to the word line WLk. However, the present disclosure is not necessarily limited thereto, and the control logic 120 may sequentially apply the recovery voltage Vrcy to the post word line postWL.

The program execution period PGM_EXE may be a period from the third time t2 to the fourth time t43.

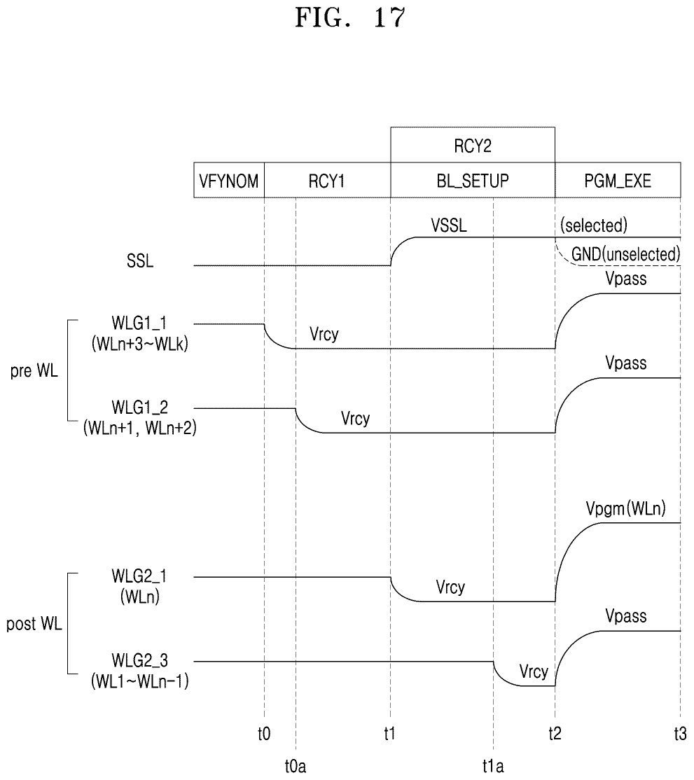

FIG. 17 is a timing diagram for explaining a first recovery operation and a second recovery operation according to one or more implementations. FIG. 17 shows that a recovery operation is sequentially performed on the pre word line preWL and the post word line postWL. In FIG. 17, it is assumed that the pre word lines preWL are the word line WLn+1 to the word line WLk of FIG. 5A. In comparison with FIG. 12, the second recovery period RCY2 and the bit line setup period BL_SETUP may start simultaneously. Redundant descriptions with those given with reference to FIGS. 12 and 15 are omitted. Hereinafter, FIGS. 5A and 12 are referred to together.

In the first recovery period RCY1, the control logic (e.g., 120 of FIG. 1) may sequentially perform the first recovery operation. For example, the recovery voltage Vrcy may be applied to the word lines WLk to WLn+3 included in the first word line group WLG1_1 at the first time t0, and the recovery voltage Vrcy may be applied to the word lines WLn+1 and WLn+2 included in the first word line group WLG1_2 at the time t0a.

At the second time t1 after the first time t0, a setup operation of the bit line setup period BL_SETUP may start. Also, the second recovery period RCY2 may start from the second time t1. In the second recovery period RCY2, the control logic 120 may sequentially perform the second recovery operation. For example, the recovery voltage Vrcy may be applied to the word line WLn included in the second word line group WLG2_1 at the second time t1, and the recovery voltage Vrcy may be applied to the word lines WL1 to WLn−1 included in the second word line group WLG2_2 at the time t1a. In FIG. 17, the grouped first word line group WLG1 and second word line group WLG2 correspond to examples, but the present disclosure is not necessarily limited thereto.

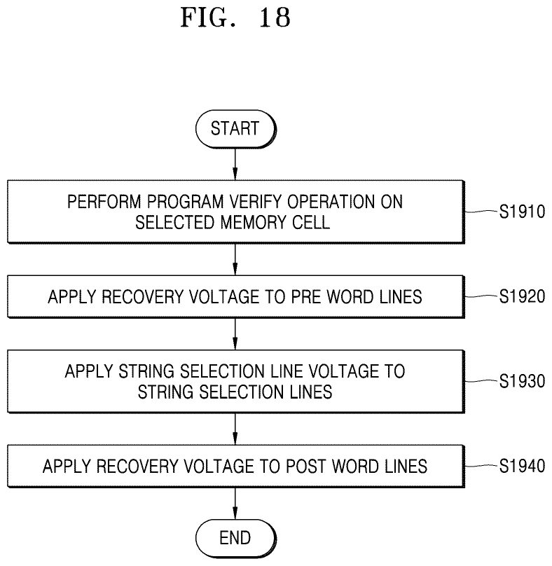

FIG. 18 is a flowchart illustrating a programming method of a memory device according to one or more implementations. Specifically, FIG. 1 shows an operating method of the control logic (e.g., 120 of FIG. 1).

In operation S1910, the memory device (e.g., 100 of FIG. 1) may perform a program verify operation on a selected memory cell. A program loop may include a bit line setup period, a program execution period, a verify period, and a recovery period. In the verify period, the memory device may perform the program verify operation on the selected memory cell. In the verify period, in order to verify whether program of the selected memory cell is successful in the program execution period, the memory device may perform the program verify operation. A program verification voltage may be applied to a selected word line during the verify period.

In operation S1920, the memory device may apply a recovery voltage to a pre word line. The memory device may perform a first recovery operation on the pre word line during a first recovery period. Some word lines among a plurality of word lines in which the recovery operation is performed before the bit line setup period may be referred to as pre word lines. The memory device may perform operations S1930 and S1940 after performing the first recovery operation on the pre word line.

In operation S1930, the memory device may apply a string selection line voltage to a string selection line. In the bit line setup period, the memory device may perform a setup operation of applying the string selection line voltage to string selection lines to activate string selection lines connected to cell strings. Operation S1930 may be performed after operation S1920. The memory device may perform the setup operation after the first recovery operation.

In operation S1940, the memory device may apply a recovery voltage to a post word line. The remaining word lines among the plurality of word lines on which the first recovery operation is not performed may be referred to as post word lines. The memory device may perform a second recovery operation on the post word line during a second recovery period. Operation S1940 may be performed after operation S1920 is performed. The first recovery period may precede the second recovery period. The memory device may perform the second recovery operation after performing the first recovery operation.

In some implementations, the second recovery period may start after the bit line setup period starts. The memory device may apply the string selection line voltage to the string selection lines in the bit line setup period, and then apply the recovery voltage to the post word line in the second recovery period. Operation S1940 may be performed after operation S1930. That is, the setup operation of the bit line setup period may start after the first recovery period, and then the second recovery period may proceed. A part of the bit line setup period may overlap the second recovery period.

In some implementations, the bit line setup period and the second recovery period may start simultaneously. The memory device may apply the string selection line voltage to the string selection lines in the bit line setup period and simultaneously apply the recovery voltage to the post word line in the second recovery period. Operations S1930 and S1940 may be performed simultaneously. After performing the first recovery operation (S1920), the memory device may simultaneously start the setup operation (S1930) of the bit line setup period and the second recovery operation (S1940).

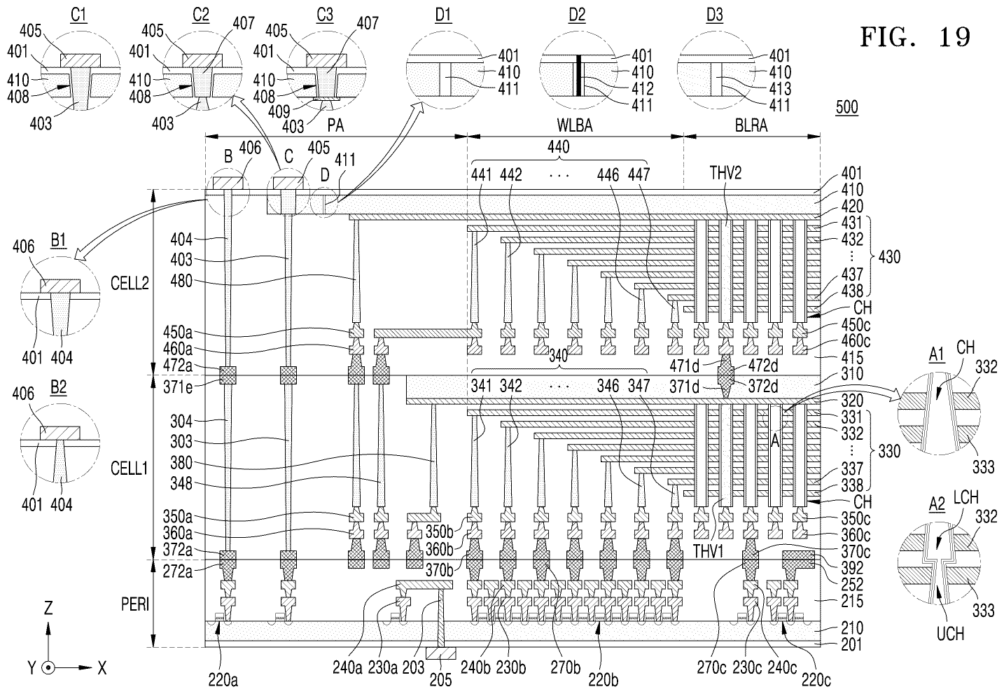

FIG. 19 is a cross-sectional view illustrating a memory device 500 having a B-VNAND structure, according to one or more implementations. When a nonvolatile memory included in the memory device is implemented as a bonding vertical NAND (B-VNAND) type flash memory, the nonvolatile memory may have a structure shown in FIG. 19. The memory device 500 of FIG. 19 may correspond to the memory device 100 of FIG. 1.

Referring to FIG. 19, the memory device 500 may have a chip to chip (C2C) structure. Here, the C2C structure may mean that at least one upper chip including a cell area CELL and a lower chip including a peripheral circuit area PERI are manufactured, and then the at least one upper chip and the lower chip are connected to each other by a bonding method. For example, the bonding method may mean a method of electrically or physically connecting a bonding metal pattern formed on the uppermost metal layer of the upper chip and a bonding metal pattern formed on the uppermost metal layer of the lower chip to each other. For example, when the bonding metal patterns include copper (Cu), the bonding method may be a Cu—Cu bonding method. As another example, the bonding metal patterns may include aluminum (Al) or tungsten (W).

The memory device 500 may include at least one upper chip including the cell area CELL. For example, as shown in FIG. 19, the memory device 500 may be implemented to include two upper chips. However, this is an example, and the number of upper chips is not limited thereto. When the memory device 500 is implemented to include two upper chips, the memory device 500 may be manufactured by manufacturing each of a first upper chip including a first cell area CELL1, a second upper chip including a second cell area CELL2, and a lower chip including the peripheral circuit area PERI, and then connecting the first upper chip, the second upper chip, and the lower chip to each other by the bonding method. The first upper chip may be inverted to be connected to the lower chip by the bonding method, and the second upper chip may be inverted to be connected to the first upper chip by the bonding method. In the following description, upper and lower portions of the first upper chip and the second upper chip are defined before the first upper chip and the second upper chip are inverted. That is, in FIG. 19, an upper portion of the lower chip means an upper portion defined with respect to +Z-axis direction, and the upper portion of each of the first upper chip and the second upper chip means the upper portion defined with respect to −Z-axis direction. However, this is an example, and only one of the first upper chip and the second upper chip may be inverted to be connected by the bonding method.

Each of the peripheral circuit area PERI and the first cell area CELL1 and the second cell area CELL2 of the memory device 500 may include an external pad bonding area PA, a word line bonding area WLBA, and a bit line bonding area BLBA. The peripheral circuit area PERI may include a first substrate 210 and a plurality of circuit devices 220a, 220b, and 220c formed on the first substrate 210. An interlayer insulating layer 215 including one or more insulating layers may be provided on the plurality of circuit devices 220a, 220b, and 220c, and a plurality of metal wirings connecting the plurality of circuit devices 220a, 220b, and 220c may be provided inside the interlayer insulating layer 215. For example, the plurality of metal wirings may include first metal wirings 230a, 230b, and 230c respectively connected to the plurality of circuit devices 220a, 220b, and 220c, and second metal wirings 240a, 240b, and 240c formed on the first metal wirings 230a, 230b, and 230c. The plurality of metal wirings may each include at least one of various conductive materials. For example, the first metal wirings 230a, 230b, and 230c may each include tungsten having a relatively high electrical resistivity, and the second metal wirings 240a, 240b, and 240c may each include copper having a relatively low electrical resistivity.

Only the first metal wirings 230a, 230b, and 230c and the second metal wirings 240a, 240b, and 240c are illustrated and described herein, but the present disclosure is not limited thereto, and at least one additional metal wiring may be further formed on the second metal wirings 240a, 240b, and 240c. In this case, the second metal wirings 240a, 240b, and 240c may each include aluminum. In addition, at least some of additional metal wirings formed on the second metal wirings 240a, 240b, and 240c may each include copper having a lower electrical resistivity than aluminum of the second metal wirings 240a, 240b, and 240c. The interlayer insulating layer 215 may be disposed on the first substrate 210 and may include an insulating material such as silicon oxide or silicon nitride.

Each of the first cell area CELL1 and the second cell area CELL2 may include at least one memory block. The first cell area CELL1 may include a second substrate 310 and a common source line 320. A plurality of word lines 330; 331 to 338 may be stacked on the second substrate 310 in a direction (the Z-axis direction) perpendicular to an upper surface of the second substrate 310. String selection lines and ground selection lines may be disposed above and below the word lines 330, and the plurality of word lines 330 may be disposed between the string selection lines and the ground selection lines. Likewise, the second cell area CELL2 may include a third substrate 410 and a common source line 420, and a plurality of word lines 430; 431 to 438 may be stacked in a direction (the Z-axis direction) perpendicular to an upper surface of the third substrate 410. The second substrate 310 and the third substrate 410 may include various materials, and may each be, for example, a silicon substrate, a silicon-germanium substrate, a germanium substrate, or a substrate having a monocrystalline epitaxial layer grown on a monocrystalline silicon substrate. A plurality of channel structures CH may be formed in each of the first cell area CELL1 and the second cell area CELL2.

In some implementations, as shown in A1, the channel structure CH may be provided in the bit line bonding area BLBA, extend in the direction perpendicular to the upper surface of the second substrate 310, and penetrate the word lines 330, the string selection lines, and the ground selection lines. The channel structure CH may include a data storage layer, a channel layer, a buried insulating layer, etc. The channel layer may be electrically connected to a first metal wiring 350c and a second metal wiring 360c in the bit line bonding area BLBA. For example, the second metal wiring 360c may be a bit line, and may be connected to the channel structure CH through the first metal wiring 350c. The bit line 360c may extend in a first direction (Y-axis direction) parallel to the upper surface of the second substrate 310.

In some implementations, as shown in A2, the channel structure CH may include a lower channel LCH and an upper channel UCH connected to each other. For example, the channel structure CH may be formed through a process of the lower channel LCH and a process of the upper channel UCH. The lower channel LCH may extend in the direction perpendicular to the upper surface of the second substrate 310 and penetrate the common source line 320 and the lower word lines 331 and 332. The lower channel LCH may include a data storage layer, a channel layer, a buried insulating layer, etc., and may be connected to the upper channel UCH. The upper channel UCH may penetrate the upper word lines 333 to 338. The upper channel UCH may include a data storage layer, a channel layer, a buried insulating layer, etc., and the channel layer of the upper channel UCH may be electrically connected to the first metal wiring 350c and the second metal wiring 360c. As a length of a channel increases, it may become difficult to form the channel having a constant width due to process reasons. The memory device 500 according to one or more implementations may include the channel having an improved width uniformity through the lower channel LCH and the upper channel UCH formed by sequential processes.

As shown in A2, when the channel structure CH is formed to include the lower channel LCH and the upper channel UCH, a word line located near a boundary between the lower channel LCH and the upper channel UCH may be a dummy word line. For example, the word line 332 and the word line 333 forming the boundary between the lower channel LCH and the upper channel UCH may be dummy word lines. In this case, data may not be stored in memory cells coupled to the dummy word line. Alternatively, the number of pages corresponding to the memory cells coupled to the dummy word line may be less than the number of pages corresponding to memory cells connected to a general word line. A voltage level applied to the dummy word line may be different from a voltage level applied to the general word line, and accordingly, an influence of a non-uniform channel width between the lower channel LCH and the upper channel UCH on the operation of the memory device 500 may be reduced.

Meanwhile, A2 shows that the number of lower word lines 331 and 332 through which the lower channel LCH penetrates is less than the number of upper word lines 333 to 338 through which the upper channel UCH penetrates. However, this is an example, and the present disclosure is not limited thereto. As another example, the number of lower word lines penetrating the lower channel LCH may be equal to or greater than the number of upper word lines penetrating the upper channel UCH. In addition, the structure and connection relationship of the channel structure CH disposed in the first cell area CELL1 described above may be equally applied to the channel structure CH disposed in the second cell area CELL2.

In the bit line bonding area BLBA, a first through electrode THV1 may be provided in the first cell area CELL1, and a second through electrode THV2 may be provided in the second cell area CELL2. The first through electrode THV1 may penetrate the common source line 320 and the plurality of word lines 330. However, this is an example, and the first through electrode THV1 may further penetrate the second substrate 310. The first through electrode THV1 may include a conductive material. Alternatively, the first through electrode THV1 may include a conductive material surrounded by an insulating material. The second through electrode THV2 may also be provided in the same shape and structure as the first through electrode THV1.

The first through electrode THV1 and the second through electrode THV2 may be electrically connected to each other through a first through metal pattern 372d and a second through metal pattern 472d. The first through metal pattern 372d may be formed on a lower end of the first upper chip including the first cell area CELL1, and the second through metal pattern 472d may be formed on an upper end of the second upper chip including the second cell area CELL2. The first through electrode THV1 may be electrically connected to the first metal wiring 350c and the second metal wiring 360c. A lower via 371d may be formed between the first through electrode THV1 and the first through metal pattern 372d, and an upper via 471d may be formed between the second through electrode THV2 and the second through metal pattern 472d. The first through metal pattern 372d and the second through metal pattern 472d may be connected to each other by the bonding method.

In addition, in the bit line bonding area BLBA, an upper metal pattern 252 may be formed on the uppermost metal layer of the peripheral circuit area PERI, and an upper metal pattern 392 having the same shape as the upper metal pattern 252 may be formed on the uppermost metal layer of the first cell area CELL1. The upper metal pattern 392 of the first cell area CELL1 and the upper metal pattern 252 of the peripheral circuit area PERI may be electrically connected to each other by the bonding method. In the bit line bonding area BLBA, the bit line 360c may be electrically connected to a page buffer included in the peripheral circuit area PERI. For example, some of the circuit devices 220c in the peripheral circuit area PERI may provide the page buffer, and the bit line 360c may be electrically connected to the circuit devices 220c providing the page buffer through the upper bonding metal 370c of the first cell area CELL1 and the upper bonding metal 270c of the peripheral circuit area PERI.

In the word line bonding area WLBA, the word lines 330 of the first cell area CELL1 may extend in a second direction (X-axis direction) parallel to the upper surface of the second substrate 310 and may be connected to a plurality of cell contact plugs 340; 341 to 347. A first metal wiring 350b and a second metal wiring 360b may be sequentially connected to upper portions of the cell contact plugs 340 connected to the word lines 330. The cell contact plugs 340 may be connected to the peripheral circuit area PERI through the upper bonding metal 370b of the first cell area CELL1 and the upper bonding metal 270b of the peripheral circuit area PERI in the word line bonding area WLBA.

The cell contact plugs 340 may be electrically connected to a row decoder included in the peripheral circuit area PERI. For example, some of the circuit devices 220b in the peripheral circuit area PERI may provide the row decoder, and the cell contact plugs 340 may be electrically connected to the circuit devices 220b providing the row decoder through the upper bonding metal 370b in the first cell area CELL1 and the upper bonding metal 270b in the peripheral circuit area PERI. In some implementations, operating voltages of the circuit devices 220b providing the row decoder may be different from operating voltages of the circuit devices 220c providing the page buffer. For example, the operating voltages of the circuit devices 220c providing the page buffer may be greater than the operating voltages of the circuit devices 220b providing the row decoder.

Likewise, in the word line bonding area WLBA, the word lines 430 of the second cell area CELL2 may extend in the second direction (X-axis direction) parallel to the upper surface of the third substrate 410 and may be connected to a plurality of cell contact plugs 440; 441 to 447. The cell contact plugs 440 may be connected to the peripheral circuit area PERI through an upper metal pattern of the second cell area CELL2, a lower metal pattern and an upper metal pattern of the first cell area CELL1, and the cell contact plug 348.

In the word line bonding area WLBA, the upper bonding metal 370b may be formed in the first cell area CELL1, and the upper bonding metal 270b may be formed in the peripheral circuit area PERI. The upper bonding metal 370b of the first cell area CELL1 and the upper bonding metal 270b of the peripheral circuit area PERI may be electrically connected to each other by the bonding method. The upper bonding metal 370b and the upper bonding metal 270b may each include aluminum, copper, tungsten, etc.

In the external pad bonding area PA, a lower metal pattern 371e may be formed on a lower portion of the first cell area CELL1, and an upper metal pattern 472a may be formed on an upper portion of the second cell area CELL2. The lower metal pattern 371e of the first cell area CELL1 and the upper metal pattern 472a of the second cell area CELL2 may be connected to each other in the external pad bonding area PA by the bonding method. Likewise, an upper metal pattern 372a may be formed on an upper portion of the first cell area CELL1, and an upper metal pattern 272a may be formed on an upper portion of the peripheral circuit area PERI. The upper metal pattern 372a of the first cell area CELL1 and the upper metal pattern 272a of the peripheral circuit area PERI may be connected to each other by the bonding method.

Common source line contact plugs 380 and 480 may be disposed in the outer pad bonding area PA. The common source line contact plugs 380 and 480 may each include a metal, a metal compound, or a conductive material such as doped polysilicon. The common source line contact plug 380 of the first cell area CELL1 may be electrically connected to the common source line 320, and the common source line contact plug 480 of the second cell area CELL2 may be electrically connected to the common source line 420. A first metal wiring 350a and a second metal wiring 360a may be sequentially stacked on an upper portion of the common source line contact plug 380 in the first cell area CELL1, and a first metal wiring 450a and a second metal wiring 460a may be sequentially stacked on an upper portion of the common source line contact plug 480 in the second cell area CELL2.

First to third input/output pads 205, 405, and 406 may be disposed in the external pad bonding area PA. A lower insulating layer 201 may cover a lower surface of the first substrate 210, and the first input/output pad 205 may be formed on the lower insulating layer 201. The first input/output pad 205 may be connected to at least one of the plurality of circuit devices 220a disposed in the peripheral circuit area PERI through the first input/output contact plug 203, and may be separated from the first substrate 210 by the lower insulating layer 201. In addition, a side insulating layer may be disposed between the first input/output contact plug 203 and the first substrate 210 to electrically separate the first input/output contact plug 203 from the first substrate 210.

An upper insulating layer 401 covering the upper surface of the third substrate 410 may be formed on the third substrate 410. The second input/output pad 405 and/or the third input/output pad 406 may be disposed on the upper insulation layer 401. The second input/output pad 405 may be connected to at least one of the plurality of circuit devices 220a disposed in the peripheral circuit area PERI through second input/output contact plugs 403 and 303, and the third input/output pad 406 may be connected to at least one of the plurality of circuit devices 220a disposed in the peripheral circuit area PERI through third input/output contact plugs 404 and 304.

The third substrate 410 may not be disposed in an area in which an input/output contact plug is disposed. For example, as shown in B, the third input/output contact plug 404 may be separated from the third substrate 410 in a direction parallel to the upper surface of the third substrate 410, and may be connected to the third input/output pad 406 through an interlayer insulating layer 415 of the second cell area CELL2. In this case, the third input/output contact plug 404 may be formed by various processes.

For example, as shown in B1, the third input/output contact plug 404 may extend in the third direction (Z-axis direction) and may be formed to have a diameter increasing toward the upper insulating layer 401. That is, a diameter of the channel structure CH described in A1 may be formed to decrease toward the upper insulating layer 401, while the diameter of the third input/output contact plug 404 may be formed to increase toward the upper insulating layer 401. For example, the third input/output contact plug 404 may be formed after the second cell area CELL2 and the first cell area CELL1 are combined by the bonding method.

In addition, as shown in B2, the third input/output contact plug 404 may extend in the third direction (the Z-axis direction) and may be formed to have the diameter decreasing toward the upper insulating layer 401. That is, the diameter of the third input/output contact plug 404 may be formed to decrease toward the upper insulating layer 401, like the channel structure CH. For example, the third input/output contact plug 404 may be formed together with the cell contact plugs 440 before bonding the second cell area CELL2 and the first cell area CELL1.

In another implementation, an input/output contact plug may be disposed to overlap the third substrate 410. For example, as shown in C, the second input/output contact plug 403 may be formed to penetrate the interlayer insulating layer 415 of the second cell area CELL2 in the third direction (Z-axis direction), and may be electrically connected to the second input/output pad 405 through the third substrate 410. In this case, a connection structure between the second input/output contact plug 403 and the second input/output pad 405 may be implemented in various ways.

For example, as shown in C1, an opening 408 penetrating the third substrate 410 may be formed, and the second input/output contact plug 403 may be directly connected to the second input/output pad 405 through the opening 408 formed in the third substrate 410. In this case, as shown in C1, a diameter of the second input/output contact plug 403 may be formed to increase toward the second input/output pad 405. However, this is an example, and the diameter of the second input/output contact plug 403 may be formed to decrease toward the second input/output pad 405.

For example, as shown in C2, the opening 408 penetrating the third substrate 410 may be formed, and a contact 407 may be formed in the opening 408. One end of the contact 407 may be connected to the second input/output pad 405, and the other end may be connected to the second input/output contact plug 403. Accordingly, the second input/output contact plug 403 may be electrically connected to the second input/output pad 405 through the contact 407 in the opening 408. In this case, as shown in C2, a diameter of the contact 407 may increase toward the second input/output pad 405, and the diameter of the second input/output contact plug 403 may decrease toward the second input/output pad 405. For example, the third input/output contact plug 403 may be formed together with the cell contact plugs 440 before bonding the second cell area CELL2 and the first cell area CELL1, and the contact 407 may be formed after bonding the second cell area CELL2 and the first cell area CELL1.

Furthermore, as shown in C3, a stopper 409 may be formed on an upper surface of the opening 408 of the third substrate 410 as compared to C2. The stopper 409 may be a metal wiring formed on the same layer as the common source line 420. However, this is an example, and the stopper 409 may be a metal wiring formed on the same layer as at least one of the word lines 430. The second input/output contact plug 403 may be electrically connected to the second input/output pad 405 through the contact 407 and the stopper 409.

Meanwhile, similar to the second input/output contact plug 403 and the third input/output contact plug 404 in the second cell area CELL2, each of the second input/output contact plug 303 and the third input/output contact plug 304 in the first cell area CELL1 may be formed to have a diameter decreasing toward the lower metal pattern 371e or increasing toward the lower metal pattern 371e.

Meanwhile, according to some implementations, a slit 411 may be formed in the third substrate 410. For example, the slit 411 may be formed at an arbitrary position in the external pad bonding area PA. For example, as shown in D, the slit 411 may be disposed between the second input/output pad 405 and the cell contact plugs 440 in a planar view. However, this is an example, and the slit 411 may be formed such that the second input/output pad 405 is disposed between the slit 411 and the cell contact plugs 440 in a planar view.

For example, as shown in D1, the slit 411 may be formed to penetrate the third substrate 410. The slit 411 may be used, for example, to prevent the third substrate 410 from being finely divided when forming the opening 408. However, this is an example, and the slit 411 may be formed to have a depth of about 60 % to about 70 % with respect to a thickness of the third substrate 410.

In addition, for example, as shown in D2, a conductive material 412 may be formed in the slit 411. The conductive material 412 may be used, for example, to discharge, to the outside, a leakage current generated during driving of circuit devices in the external pad bonding area PA. In this case, the conductive material 412 may be connected to an external ground line.

In addition, for example, as shown in D3, an insulating material 413 may be formed in the slit 411. The insulating material 413 may be formed, for example, to electrically separate the second input/output pad 405 and the second input/output contact plug 403 disposed in the outer pad bonding area PA from the word line bonding area WLBA. The insulating material 413 is formed inside the slit 411, thereby preventing a voltage provided through the second input/output pad 405 from affecting a metal layer disposed on the third substrate 410 in the word line bonding area WLBA.

According to some implementations, the first to third input/output pads 205, 405, and 406 may be selectively formed. For example, the memory device 500 may be implemented to include only the first input/output pad 205 disposed on the first substrate 210, only the second input/output pad 405 disposed on the third substrate 410, or only the third input/output pad 406 disposed on the upper insulating layer 401.

According to some implementations, at least one of the second substrate 310 of the first cell area CELL1 or the third substrate 410 of the second cell area CELL2 may be used as a sacrificial substrate, and may be completely or partially removed before or after a bonding process. An additional layer may be stacked after a substrate is removed. For example, the second substrate 310 of the first cell area CELL1 may be removed before or after bonding between the peripheral circuit area PERI and the first cell area CELL1, and an insulating layer covering the upper surface of the common source line 320 or a conductive layer for connection may be formed. Similarly, the third substrate 410 of the second cell area CELL2 may be removed before or after bonding between the first cell area CELL1 and the second cell area CELL2, and the upper insulating layer 401 covering the upper surface of the common source line 420 or a conductive layer for connection may be formed.

According to the present implementation, the upper bonding metals 270c of the peripheral circuit area PERI may be disposed on an upper portion of a page buffer circuit area, and may be disposed in a matrix form according to a first direction Y and a second direction X. The page buffer circuit area may correspond to the bit line bonding area BLBA. For example, the upper bonding metals 270c may be grouped into a plurality of bonding pad groups, and each bonding pad group may include upper bonding metals disposed in a row in the first direction Y. According to the present implementation, the peripheral circuit area PERI may include a plurality of through wirings extending in the first direction Y. For example, each through wiring may be disposed between adjacent bonding pad groups.

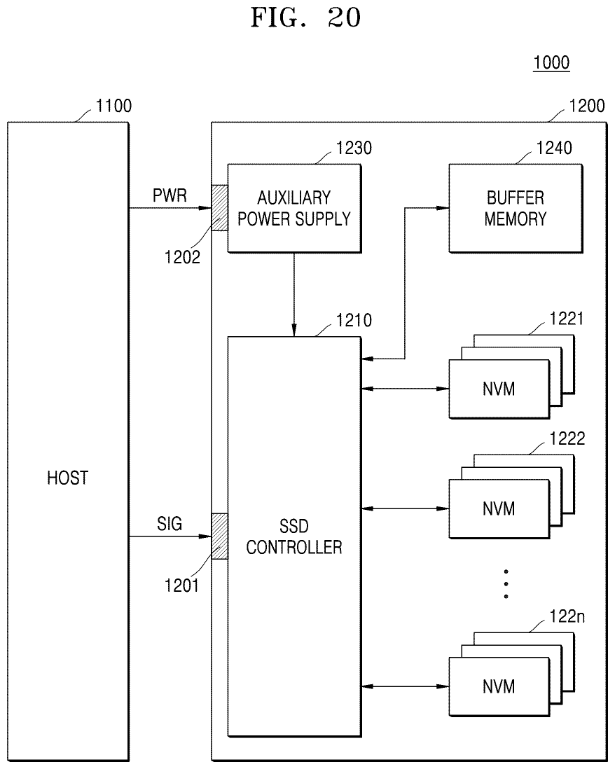

FIG. 20 is a block diagram illustrating a solid state drive (SSD) system 1000 to which a memory device according to one or more implementations is applied.

Referring to FIG. 20, the SSD system 1000 may include a host 1100 and an SSD 1200. The SSD 1200 exchanges a signal SIG with the host 1100 through a signal connector and receives a power PWR through a power connector. The SSD 1200 may include an SSD controller 1210, an auxiliary power supply 1230, a buffer memory 1240, and nonvolatile memory devices (NVMs) 1221, 1222, . . . 122n. For example, the NVMs 1221, 1222, . . . 122n may be vertically stacked NAND flash memory devices. In this regard, the SSD 1200 may be implemented using the above-described implementations with reference to FIGS. 1 to 19.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination m ay be directed to a subcombination or variation of a subcombination.

What is claimed is:

1. A memory device comprising:
a memory cell array comprising cell strings, the cell strings including a plurality of memory cells connected to a plurality of word lines that are disposed in series, the plurality of word lines comprising a first group of word lines and a second group of word lines; and
a control logic configured to perform a program verify operation on a selected memory cell of the plurality of memory cells in a verify period and recover the plurality of word lines after the verify period,
wherein the control logic is configured to:
in a bit line setup period, perform a setup operation in which a string selection line voltage is applied to string selection lines connected to at least one of the cell strings to activate the string selection lines;
in a first recovery period before the setup operation is performed, apply a first recovery voltage to the first group of word lines; and
in a second recovery period after the first recovery period, apply a second recovery voltage to the second group of word lines.

2. The memory device of claim 1, wherein the control logic is configured to apply the second recovery voltage to the second group of word lines in the second recovery period after performing the setup operation in the bit line setup period.

3. The memory device of claim 1, wherein the control logic is configured to perform the setup operation in the bit line setup period after the first recovery period and simultaneously apply the second recovery voltage to at least one word line of the second group of word lines in the second recovery period.

4. The memory device of claim 1, wherein the control logic is configured to recover at least two word lines of the plurality of word lines by simultaneously applying the first recovery voltage to the at least two word lines in the first recovery period.

5. The memory device of claim 1, wherein
the first group of word lines include at least two word lines, and the first group of word lines comprises first word line subgroups each including at least one word line, and
the control logic is configured to apply, in the first recovery period, the first recovery voltage to each of the first word line subgroups at a different time.

6. The memory device of claim 1, wherein the control logic is configured to recover the second group of word lines by simultaneously applying the second recovery voltage to the second group of word lines in the second recovery period.

7. The memory device of claim 1, wherein
the second group of word lines comprises second word line subgroups each including at least one word line, and
the control logic is configured to apply, in the second recovery period, the second recovery voltage to each of the second word line subgroups at a different time.

8. The memory device of claim 7, wherein
the second word line subgroups are arranged based on an order in which a program operation is performed, and
the control logic is configured to apply, in the second recovery period, the second recovery voltage first to a second word line subgroup of the second word line subgroups on which the program operation is performed first.

9. The memory device of claim 1, wherein
the plurality of word lines comprise:
a selected word line,
upper word lines on which a program operation is performed before the selected word line, and
lower word lines on which the program operation is performed after the selected word line, and
the control logic is configured to apply the first recovery voltage to at least one of the upper word lines in the first recovery period.

10. The memory device of claim 9, wherein the control logic is configured to apply, in the first recovery period, the first recovery voltage to an uppermost word line group of the upper word lines, the uppermost word line group including an uppermost word line of the plurality of word lines on which the program operation is performed first.

11. The memory device of claim 1, wherein the first recovery voltage is same as the second recovery voltage.

12. The memory device of claim 1, wherein the control logic is configured to maintain, during the bit line setup period, the first recovery voltage that is applied to the first group of word lines in the first recovery period.

13. The memory device of claim 1, wherein the control logic is configured to maintain, during the second recovery period, the string selection line voltage that is applied to the string selection lines in the bit line setup period.

14. A programming method of a memory device comprising cell strings, the cell strings including a plurality of memory cells connected to a plurality of word lines that are disposed in series, the programming method comprising:
performing a program verify operation on a selected memory cell of the plurality of memory cells;
applying a recovery voltage to pre word lines of the plurality of word lines;
applying a string selection line voltage to string selection lines connected to at least one of the cell strings to activate the string selection lines; and
applying the recovery voltage to post word lines of the plurality of word lines,
wherein the recovery voltage is configured to be applied to the pre word lines before applying the string selection line voltage to the string selection lines.

15. The programming method of claim 14, wherein the string selection line voltage is configured to be applied to the string selection lines before applying the recovery voltage to the post word lines.

16. The programming method of claim 14, wherein applying the string selection line voltage to the string selection lines and applying the recovery voltage to the post word lines are configured to be performed simultaneously.

17. The programming method of claim 14, wherein
the pre word lines comprise first word line groups each including at least one of the pre word lines of the plurality of word lines, the first word line groups being arranged based on an order in which a program operation is performed, and
applying the recovery voltage to the pre word lines comprises sequentially applying the recovery voltage to each of the first word line groups in order of proximity to an uppermost word line of the plurality of word lines on which the program operation is performed first.

18. The programming method of claim 14, wherein
the post word lines comprise second word line groups each including at least one of the post word lines of the plurality of word lines, the second word line groups being arranged based on an order in which a program operation is performed, and
applying the recovery voltage to the post word lines comprises sequentially applying the recovery voltage to each of the second word line groups in order of proximity to an uppermost word line of the plurality of word lines on which the program operation is performed first.

19. A memory device comprising:
a memory cell array comprising a plurality of cell strings, the cell strings including a string selection transistor, memory cells connected to a plurality of word lines, and a ground selection transistor disposed in series, and
a control logic configured to recover the plurality of word lines,
wherein the plurality of word lines comprise a selected word line, upper word lines on which a program operation is configured to be performed before the selected word line, and lower word lines on which the program operation is configured to be performed after the selected word line,
wherein the upper word lines comprise a first group of upper word lines and a second group of upper word lines, the first group of upper word lines comprising at least one of the upper word lines,
wherein the control logic is configured to:
turn on the ground selection transistor in a verify period;
apply a recovery voltage to the first group of upper word lines in a first recovery period after the verify period;
turn on the string selection transistor in a bit line setup period after the first recovery period; and
apply, in a second recovery period, the recovery voltage to the second group of upper word lines, the selected word line and the lower word lines, and
wherein at least a part of the bit line setup period overlaps the second recovery period.

20. The memory device of claim 19, wherein
the upper word lines comprise an uppermost word line of the plurality of word lines on which the program operation is configured to be performed first, and
the control logic is configured to apply the recovery voltage to the uppermost word line first in the first recovery period.
